(19) United States
(12) Patent Application Publication
(10) Pub. No.: US 2026/0223428 A1
(43) Pub. Date: Jul. 30, 2026

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 19/573,697

(22) Filed: Mar. 20, 2026

Related U.S. Application Data
(63) Continuation-in-part of application No. 19/436,888, filed on Dec. 30, 2025.
Application No. 19/436,888 is a continuation of application No. 18/747,616, filed on Jun. 19, 2024, now Pat. No. 12,538,552.
Application No. 18/747,616 is a continuation of application No. 18/194,490, filed on Mar. 31, 2023, now Pat. No. 12,046,645.
Application No. 18/194,490 is a continuation of application No. 17/205,943, filed on Mar. 18, 2021, now Pat. No. 11,640,976.

(30) Foreign Application Priority Data
Sep. 22, 2020 (KR) 10-2020-0122210

(51) Int. Cl. H10D 64/23; H10D 62/17

(52) U.S. Cl. CPC H10D 64/252; H10D 62/292

(57) ABSTRACT

A semiconductor device includes a stacked structure including word lines; a first select line disposed over the stacked structure; a second select line disposed over the stacked structure; an isolation insulating pattern disposed between the first select line and the second select line; a first channel layer extending through the stacked structure and the first select line; a second channel layer extending through the stacked structure and the second select line; a data storage pattern surrounding the first channel layer; and an insulating protective layer disposed on the first select line, wherein the insulating protective layer has a protruding part that extends into the first select line.

### CROSS-REFERENCE TO RELATED APPLICATIONS

The present application is a continuation-in-part application of U.S. Patent Application No. 19/436,888, filed on December 30, 2025, which is a continuation application of U.S. Patent Application No. 18/747,616, filed on June 19, 2024, which is continuation application of U.S. Patent Application No. 18/194,490, filed on March 31, 2023, which is a continuation application of U.S. Patent Application No. 17/205,943, filed on March 18, 2021, which claims priority under 35 U.S.C. § 119(a) to Korean patent application number 10-2020-0122210 filed on September 22, 2020, in the Korean Intellectual Property Office, the entire contents of which applications are incorporated herein by reference.

### BACKGROUND

### 1. Technical Field

Various embodiments of the disclosure relate generally to an electronic device, and more particularly, to a semiconductor device and a method of manufacturing the semiconductor device.

### 2. Related Art

The increase in integration density of two-dimensional memory devices in which memory cells are formed in a single layer over a substrate has recently been limited. Thus, three-dimensional memory devices have been proposed in which memory cells are stacked in a vertical direction over a substrate. In addition, various structures and manufacturing methods have been developed to improve the operational reliability of three-dimensional memory devices.

### SUMMARY

According to an embodiment, a semiconductor device may include a stacked structure including word lines; a first select line disposed over the stacked structure; a second select line disposed over the stacked structure; an isolation insulating pattern disposed between the first select line and the second select line; a first channel layer extending through the stacked structure and the first select line; a second channel layer extending through the stacked structure and the second select line; a data storage pattern surrounding the first channel layer; and an insulating protective layer disposed on the first select line, wherein the insulating protective layer has a protruding part that extends into the first select line.

According to an embodiment, a semiconductor device may include a stacked structure including word lines and insulating layers that are stacked alternately with each other; a first select line disposed over the stacked structure; a second select line disposed over the stacked structure; an isolation insulating pattern disposed between the first select line and the second select line, wherein the isolation insulating pattern protrudes into a top insulating layer among the insulating layers; a first channel layer extending through the stacked structure and the first select line; a second channel layer extending through the stacked structure and the second select line; and a data storage pattern between the first channel layer and the stacked structure, wherein the data storage pattern is not interposed between the first channel layer and the first select line, wherein the isolation insulating pattern overlaps the data storage pattern in the top insulating layer.

According to an embodiment, a semiconductor device may include a stacked structure including word lines and insulating layers that are stacked alternately with each other; a first select line disposed over the stacked structure; a second select line disposed over the stacked structure; an isolation insulating pattern disposed between the first select line and the second select line; a first channel layer extending through the first select line; a second channel layer extending through the second select line; and a data storage pattern extending through the stacked structure, wherein the data storage pattern is not interposed between the first channel layer and the first select line, wherein the first select line includes a first sidewall surrounding the first channel layer, each of the word lines includes a second sidewall surrounding the first channel layer, and the first sidewall is closer to the first channel layer than the second sidewall.

### BRIEF DESCRIPTION OF THE DRAWINGS

FIGS. 1A to 1E are diagrams illustrating the structure of a semiconductor device according to an embodiment of the present disclosure;

FIGS. 2A to 2F, FIGS. 3A to 3C, and FIGS. 4A to 4D, FIGS. 5A to 5C, FIGS. 6A to 6C, FIGS. 7A to 7D, and FIGS. 8A to 8D are diagrams illustrating a manufacturing method of a semiconductor device according to an embodiment of the present disclosure;

FIG. 9 is a block diagram illustrating a memory system according to an embodiment of the present disclosure;

FIG. 10 is a block diagram illustrating a memory system according to an embodiment of the present disclosure;

FIG. 11 is a block diagram illustrating a memory system according to an embodiment of the present disclosure;

FIG. 12 is a block diagram illustrating a memory system according to an embodiment of the present disclosure; and

FIG. 13 is a block diagram illustrating a memory system according to an embodiment of the present disclosure.

FIG. 14 is a diagram illustrating the structure of a semiconductor device in accordance with an embodiment.

FIG. 15 is a diagram illustrating the structure of a semiconductor device in accordance with an embodiment.

FIG. 16 is a diagram illustrating the structure of a semiconductor device in accordance with an embodiment.

FIG. 17A is a diagram illustrating the structure of a semiconductor device in accordance with an embodiment.

FIG. 17B is a diagram illustrating the structure of a semiconductor device in accordance with an embodiment.

FIG. 17C is a diagram illustrating the structure of a semiconductor device in accordance with an embodiment.

FIG. 18A is a diagram illustrating the structure of a semiconductor device in accordance with an embodiment.

FIG. 18B is a diagram illustrating the structure of a semiconductor device in accordance with an embodiment.

FIG. 18C is a diagram illustrating the structure of a semiconductor device in accordance with an embodiment.

FIG. 18D is a diagram illustrating the structure of a semiconductor device in accordance with an embodiment.

FIGS. 19A and 19B are diagrams illustrating the structure of a semiconductor device in accordance with an embodiment.

FIGS. 20A to 20D are a diagram illustrating the structure of a semiconductor device in accordance with an embodiment.

FIGS. 21A and 21B are diagrams illustrating the structure of a semiconductor device in accordance with an embodiment.

FIGS. 22A and 22B are diagrams illustrating the structure of a semiconductor device in accordance with an embodiment.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Various embodiments are directed to a semiconductor device having a stabilized structure and improved characteristics, and a method of manufacturing the semiconductor device.

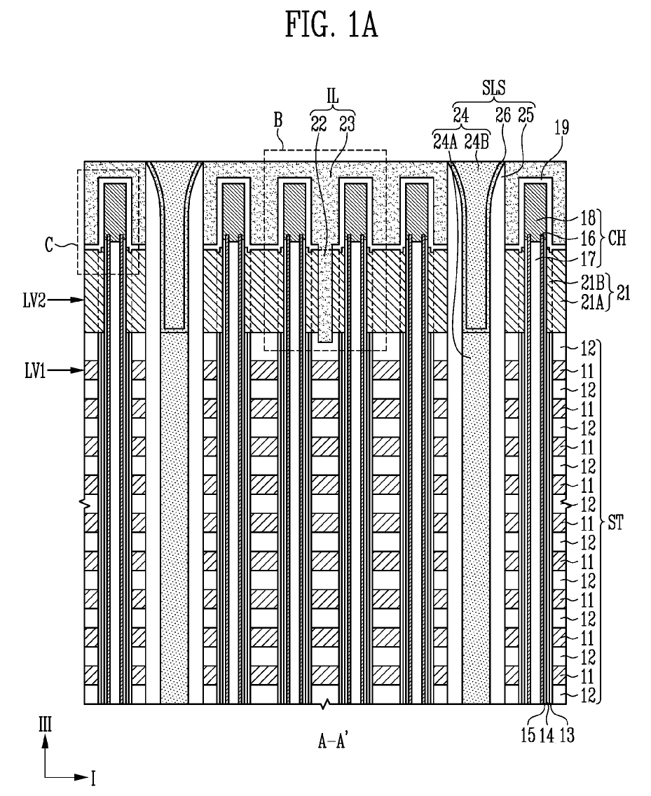

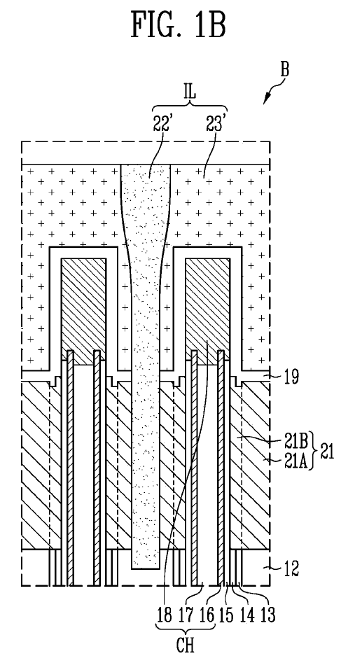

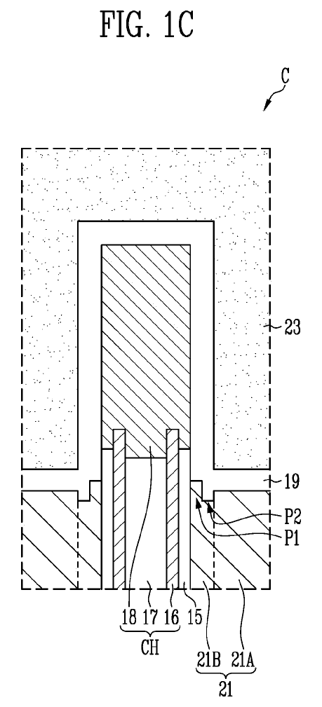

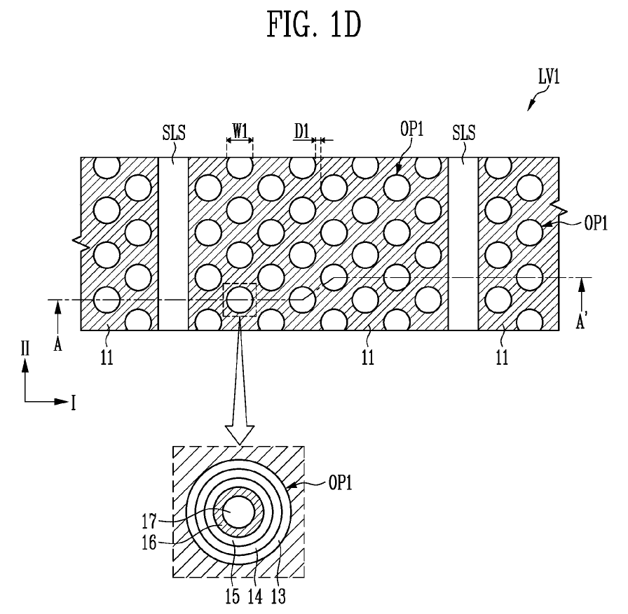

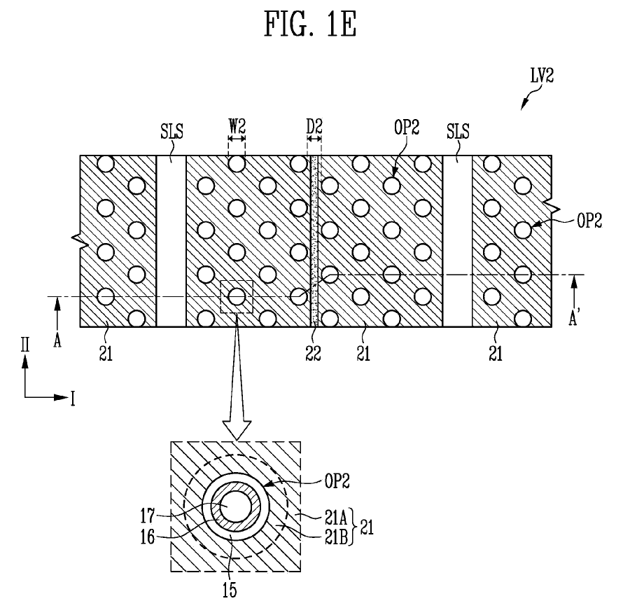

FIGS. 1A to 1E are diagrams illustrating the structure of a semiconductor device according to an embodiment of the present disclosure. FIG. 1A is an A-A’ cross-sectional view of FIGS. 1D and 1E, FIG. 1D is a plan view of a first level LV1 of FIG. 1A, and FIG. 1E is a plan view of a second level LV2 of FIG. 1A. FIG. 1B is an enlarged view of a portion B of FIG. 1A and FIG. 1C is an enlarged view of a portion C of FIG. 1A.

Referring to FIGS. 1A to 1C, a semiconductor device may include a stacked structure ST, a conductive structure 21, data storage patterns 14 and channel layers 16. The semiconductor device may further include blocking patterns 13, tunnel insulating layers 15, insulating cores 17, channel pads 18, an insulating protective layer 19, an isolation insulating pattern 22, an interlayer insulating layer 23, a slit structure SLS, or a combination thereof.

The stacked structure ST may include first conductive layers 11 and insulating layers 12 that are stacked on each other. The first conductive layers 11 may be gate electrodes of memory cells, or word lines. The first conductive layers 11 may include a conductive material such as polysilicon, tungsten, molybdenum, or metal. The insulating layers 12 may insulate the stacked first conductive layers 11 from each other. The insulating layers 12 may include insulating materials such as oxides, nitrides, or air gaps.

The conductive structure 21 may be stacked on the stacked structure ST. The conductive structure 21 may be a gate electrode of a select transistor, or a select line. According to an embodiment, the conductive structure 21 may include a drain select line.

The conductive structure 21 may include second conductive layers 21A and second conductive patterns 21B. The second conductive layers 21A may be located over the stacked structure ST. Each of the second conductive layers 21A may commonly surround sidewalls of the plurality of channel layers 16. Each of the second conductive patterns 21B may surround the sidewall of each of the channel layers 16. The second conductive pattern 21B may be interposed between the channel layers 16 and the second conductive layers 21A. According to an embodiment, a plurality of second conductive patterns 21B may be electrically connected to one second conductive layer 21A. The second conductive layer 21A and the second conductive patterns 21B may be formed into a single layer. Alternatively, an interface may exist between the second conductive layer 21A and the second conductive patterns 21B.

The second conductive pattern 21B may have an uneven upper surface. Referring to FIG. 1C, the second conductive pattern 21B may include either or both of a protruding portion and a depressed portion. The upper surface of the second conductive pattern 21B may include a first portion P1 adjacent to the tunnel insulating layer 15 and a second portion P2 adjacent to the second conductive layer 21A. The second portion P2 may have a different level with respect to the first portion P1. According to an embodiment, the first portion P1 may have a higher level than the second portion P2. According to an embodiment, the first portion P1 may have a higher level than the upper surface of the second conductive layer 21A. The second portion P2 may have substantially the same level as the upper surface of the second conductive layer 21A, or may have a lower level than the upper surface of the second conductive layer 21A.

The second conductive layers 21A may include a conductive material such as polysilicon, tungsten, molybdenum, or metal. The second conductive patterns 21B may have materials that are the same or different from the second conductive layers 21A. The specific resistance of the second conductive patterns 21B may be equal to or less than that of the second conductive layers 21A. The second conductive patterns 21B may include polysilicon, metal, metal nitride, metal silicide, or the like. According to an embodiment, the second conductive patterns 21B may include tungsten, tungsten nitride, tungsten silicide, molybdenum, molybdenum nitride, molybdenum silicide, titanium, titanium nitride, titanium silicide, or a combination thereof.

The channel layers 16 may pass through the stacked structure ST and the conductive structure 21 in a third direction III. The third direction III may refer to a stacking direction of the first conductive layers 11 and the insulating layers 12. The channel layers 16 may protrude above the upper surface of the conductive structure 21. The channel pads 18 may be disposed over the conductive structure 21 and protrude above the upper surface of the conductive structure 21.

Each of the channel pads 18 may be coupled to each of the channel layers 16. Referring to FIG. 1C, the channel layer 16 may protrude into the channel pad 18. Since the channel pad 18 contacts the upper surface and the sidewall of the channel layer 16, a contact area may be increased. The channel pad 18 may be formed on the insulating core 17, the channel layer 16 and the tunnel insulating layer 15.

Each of the channel layers 16 may have a central region filled up, or an open central region. The open central region of each of the channel layers 16 may be filled with the insulating core 17. The insulating cores 17 may include an insulating material such as an oxide, a nitride, or air gaps. The channel layer 16, the insulating core 17 formed in the channel layer 16, and the channel pad 18 coupled to the channel layer 16 may form a single channel structure CH.

The tunnel insulating layers 15, the data storage patterns 14 and the blocking patterns 13 may be interposed between the channel layers 16 and the blocking patterns 13. The data storage patterns 14 may include a floating gate, a charge trapping material, polysilicon, a nitride, a variable resistance material, a phase change material, a nanostructure, or the like.

The tunnel insulating layers 15, the data storage patterns 14 and the blocking patterns 13 may surround the channel layers 16. The data storage patterns 14 and the blocking patterns 13 may be located under the conductive structure 21. According to an embodiment, the data storage patterns 14 and the blocking patterns 13 may be located under the second conductive patterns 21B. In a cross-sectional view, the thickness of each second conductive pattern 21B in a first direction I may be substantially the same as the sum of the thickness of the data storage pattern 14 in the first direction I and the thickness of the blocking pattern 13 in the first direction I. The first direction I may cross the third direction III.

Upper surfaces of the data storage patterns 14 and upper surfaces of the blocking patterns 13 may be located at substantially the same or different levels from each other. The upper surfaces of the data storage patterns 14 and the upper surfaces of the blocking patterns 13 may be located at a higher level than the upper surface of the uppermost first conductive layer 11. The upper surfaces of the data storage patterns 14 and the upper surfaces of the blocking patterns 13 may be located between the upper surface of the conductive structure 21 and the lower surface of the conductive structure 21, or between the lower surface of the conductive structure 21 and the upper surface of the uppermost first conductive layer 11. The distance between the second conductive patterns 21B and the uppermost first conductive layer 11 may be ensured by ensuring the distance between the upper surfaces of the data storage patterns 14 and the uppermost first conductive layer 11. Alternately, the distance between the second conductive patterns 21B and the uppermost first conductive layer 11 may be ensured by ensuring the distance between the upper surfaces of the blocking patterns 13 and the uppermost first conductive layer 11. Therefore, a breakdown voltage may be ensured.

The tunnel insulating layers 15 may extend between the channel layers 16 and the second conductive patterns 21B. According to an embodiment, each of the tunnel insulating layers 15 may be interposed between the channel layer 16 and the data storage pattern 14 and between the channel layer 16 and the second conductive pattern 21B. The tunnel insulating layers 15 may protrude above the upper surface of the conductive structure 21.

The insulating protective layer 19 may surround the channel pads 18. The insulating protective layer 19 may surround the channel pads 18 and the tunnel insulating layers 15 and may extend along the upper surface of the conductive structure 21. The insulating protective layer 19 may be interposed between the channel pads 18 and the interlayer insulating layer 23, between the tunnel insulating layers 15 and the interlayer insulating layer 23, and between the conductive structure 21 and the interlayer insulating layer 23. The insulating protective layer 19 may include an insulating material such as an oxide or a nitride.

An insulating layer IL may be located on the conductive structure 21. The insulating layer IL may include the isolation insulating pattern 22 and the interlayer insulating layer 23. The insulating layer IL may have a single-layer or multilayer structure.

The isolation insulating pattern 22 may be stacked on the stacked structure ST. The isolation insulating pattern 22 may pass through the conductive structure 21 in the third direction III and extend to the interlayer insulating layer 23. The isolation insulating pattern 22 may be interposed between the second conductive layers 21A and insulate the second conductive layers from each other. The isolation insulating pattern 22 may contact the second conductive layers 21A at both sides thereof. At least one of the second conductive patterns 21B may contact the isolation insulating pattern 22. The isolation insulating pattern 22 may include an insulating material such as an oxide, a nitride, or air gaps. The interlayer insulating layer 23 may be located on the conductive structure 21. The interlayer insulating layer 23 may include an insulating material such as oxide or nitride.

According to an embodiment, the interlayer insulating layer 23 and the isolation insulating pattern 22 may be coupled into a single layer. Referring to FIG. 1A, a portion of the insulating layer IL that passes through the conductive structure 21 may be the isolation insulating pattern 22, and a portion of the insulating layer IL that is formed above the conductive structure 21 may be the interlayer insulating layer 23.

According to an embodiment, the insulating layer IL may have a multilayer structure. Referring to FIG. 1B, the insulating layer IL may include an isolation insulating pattern 22’ and an interlayer insulating layer 23’. An interface may be defined between the isolation insulating pattern 22’ and the interlayer insulating layer 23’. The isolation insulating pattern 22’ and the interlayer insulating layer 23’ may include different materials. The isolation insulating pattern 22’ may include an insulating material such as an oxide and a nitride. The interlayer insulating layer 23’ may include an amorphous carbon layer. The isolation insulating pattern 22’ may pass through the conductive structure 21 to extend between the channel pads 18. The isolation insulating pattern 22’ may pass through the interlayer insulating layer 23’.

The slit structure SLS may pass through the interlayer insulating layer 23, the conductive structure 21 and the stacked structure ST. The slit structure SLS may be located between the channel layers 16 adjacent to each other in the first direction I. The slit structure SLS may extend between the second conductive layers 21A and between the channel pads 18. The slit structure SLS may pass through the interlayer insulating layer 23.

The slit structure SLS may include a source contact structure 24 and an insulating spacer 25 and may further include a barrier layer 26. The source contact structure 24 may include a conductive material such as polysilicon, tungsten, molybdenum, or a metal. The source contact structure 24 may have a single layer structure or a multi-layer structure. According to an embodiment, the source contact structure 24 may include a polysilicon single layer. According to an embodiment, the source contact structure 24 may include a first contact structure 24A and a second contact structure 24B having a lower specific resistance than the first contact structure 24A. The first contact structure 24A may include polysilicon and the second contact structure 24B may include a metal. The second contact structure 24B may be separated from the uppermost first conductive layer 11 of the first conductive layers 11. The lower surface of the second contact structure 24B may be located in a higher level than the upper surface of the uppermost first conductive layer 11.

The barrier layer 26 may surround the source contact structure 24. The barrier layer 26 may be interposed between the source contact structure 24 and the insulating spacer 25. The barrier layer 26 may be interposed between the first contact structure 24A and the second contact structure 24B. The barrier layer 26 may include tungsten nitride, molybdenum nitride, tungsten nitride, tantalum nitride, or the like.

The insulating spacer 25 may be interposed between the source contact structure 24 and the first conductive layers 11 and between the source contact structure 24 and the conductive structure 21. The insulating spacer 25 may surround the sidewall of the source contact structure 24 and may include an insulating material such as an oxide, a nitride, or air gaps.

According to the above-described structure, memory cells may be located at intersections between the channel structure CH and the first conductive layers 11. Select transistors may be located at an intersection between the channel structure CH and the conductive structure 21. The memory cells may be located in the third direction III, and at least one select transistor may be stacked on the memory cells. The memory cells and at least one select transistor that are stacked on top of each other may share the channel layer 16 and the tunnel insulating layer 15. While a select transistor has a similar structure to a memory cell, the select transistor may include the second conductive pattern 21B instead of the data storage pattern 14 and the blocking pattern 13.

Referring to FIGS. 1A and 1D, each of the first conductive layers 11 may include first openings OP1. The first openings OP1 may be arranged in the first direction I and in a second direction II crossing the first direction I. Each of the first openings OP1 may have a circular cross-section, an elliptical cross-section, a polygonal cross-section, or the like. The channel layer 16, the tunnel insulating layer 15 and the data storage pattern 14 may be located in each of the first openings OP1. In addition, the blocking pattern 13 and the insulating core 17 may be located in each of the first openings OP1.

Referring to FIGS. 1A and 1E, the conductive structure 21 may include second openings OP2. The second openings OP2 may be arranged in the first direction I and the second direction II. The second openings OP2 may be located at positions corresponding to the first openings OP1. Each of the second openings OP2 may have a circular cross-section, an elliptical cross-section, a polygonal cross-section, or the like. The channel layer 16 and the tunnel insulating layer 15 may be located in each of the second openings OP2. In other words, the data storage pattern 14 and the blocking pattern 13 may not be located in the second openings OP2.

In a plan view, the second openings OP2 may have a smaller width than the first openings OP1. According to an embodiment, each of the first openings OP1 may have a first width W1 in the first direction I and each of the second openings OP2 may have a second width W2 in the first direction I. The second width W2 may be less than the first width W1.

In a plan view, the distance between the second openings OP2 may be greater than the distance between the first openings OP1. According to an embodiment, the first openings OP1 may be spaced apart from each other at a first distance D1 in the first direction I, and the second openings OP2 may be spaced apart from each other at a second distance D2 in the first direction I. The second distance D2 may be greater than the first distance D1.

The isolation insulating pattern 22 may pass through the conductive structure 21 between the second openings OP2. The second conductive layers 21A at both sides may be insulated from each other by the isolation insulating pattern 22. The isolation insulating pattern 22 may extend in the second direction II. The isolation insulating pattern 22 may contact the second conductive patterns 21B at both sides thereof. The tunnel insulating layers 15 and the second conductive patterns 21B may be interposed between the isolation insulating pattern 22 and the channel layers 16.

According to the above-described structure, since the second openings OP2 have a smaller width than the first openings OP1, the distance between the second openings OP2 may be selectively increased. In the first level LV1 where the isolation insulating pattern 22 is not formed, the first distance D1 may be maintained between the first openings OP1. In the second level LV2 where the isolation insulating pattern 22 is formed, the second distance D2 may be sufficiently maintained between the second openings OP2. Therefore, in the second level LV2, it may be possible to ensure a space where the isolation insulating pattern 22 is formed between the channel structures CH.

In addition, the sidewalls of the channel layers 16 located adjacent to the isolation insulating pattern 22 may be entirely surrounded by the second conductive patterns 21B. Therefore, the channel layers 16 located adjacent to the isolation insulating pattern 22 may serve as real channel layers, not dummy channel layers. In addition, since the select transistors have a gate all around (GAA) structure, they may have uniform characteristics.

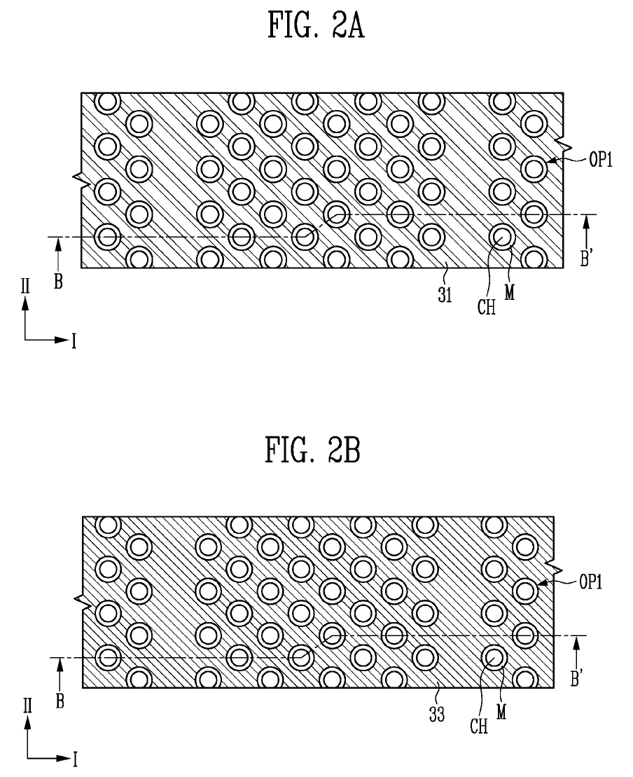

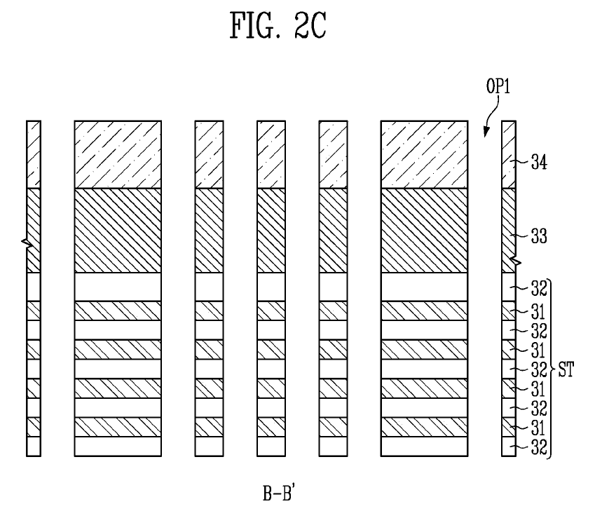

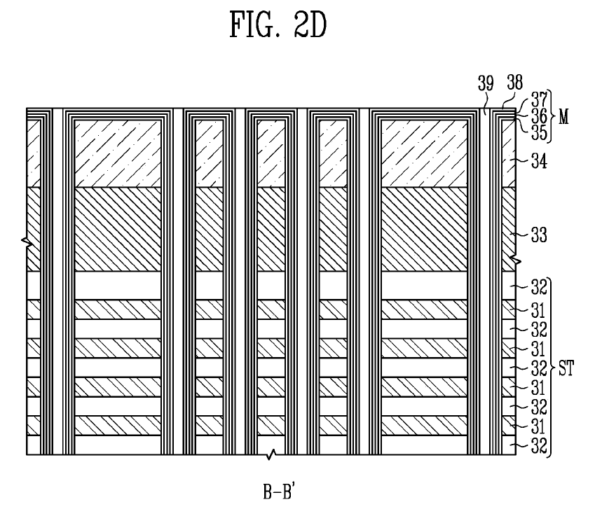

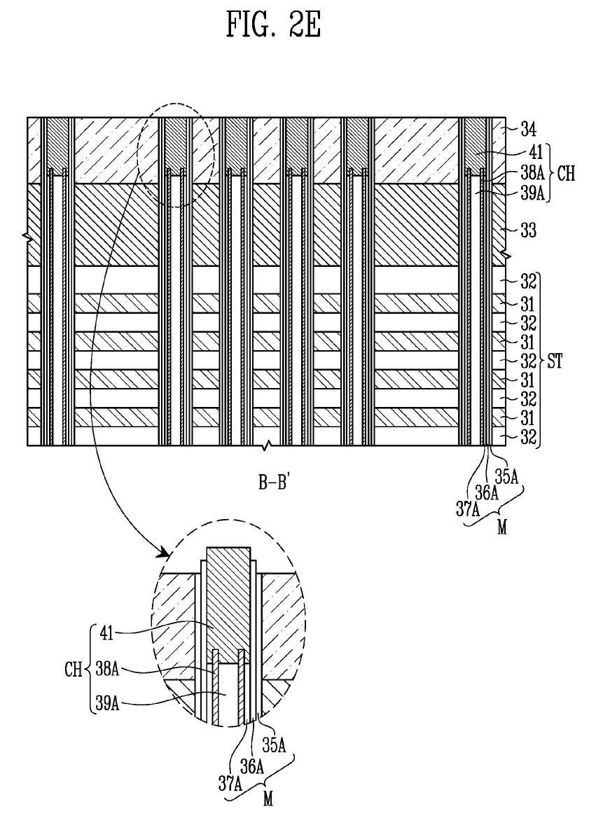

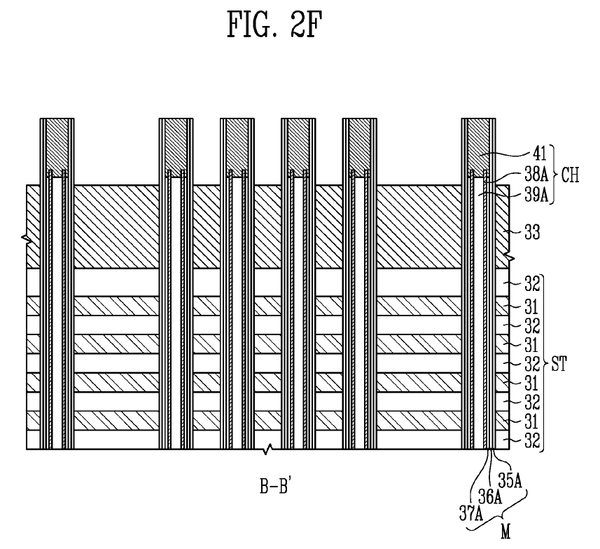

FIGS. 2A to 2F, FIGS. 3A to 3C, and FIGS. 4A to 4D, FIGS. 5A to 5C, FIGS. 6A to 6C, FIGS. 7A to 7D, and FIGS. 8A to 8D are diagrams illustrating a manufacturing method of a semiconductor device according to an embodiment of the present disclosure. FIGS. 2A, 3A, 4A, 5A, 6A, 7A, and 8A and FIGS. 2B, 3B, 4B, 5B, 6B, 7B, and 8B are plan views, and FIGS. 2C, 3C, 4C, 5C, 6C, 7C, and 8C and FIGS. 2D, 4D, 7D, and 8D are cross-sectional views. Hereinafter, any repetitive detailed description of components having already been mentioned above will be omitted.

Referring to FIGS. 2A to 2F, the stacked structure ST, a conductive layer 33, a sacrificial layer 34, the first openings OP1, the channel structures CH and memory layers M may be formed. First, referring to FIGS. 2A to 2C, the stacked structure ST may be formed on a substrate (not shown) that includes a lower structure. The lower structure may include a peripheral circuit, an interconnection structure, a source structure or the like.

The stacked structure ST may include first material layers 31 and second material layers 32 that are stacked alternately with each other. The first material layers 31 may include a material having a high etch selectivity with respect to the second material layers 32. For example, the first material layers 31 may include a sacrificial material, such as nitride, and the second material layers 32 may include an insulating material, such as oxide. For example, the first material layers 31 may include a conductive material such as polysilicon, tungsten, or molybdenum, and the second material layers 32 may include an insulating material such as an oxide. The first material layers 31 may have the same or different thicknesses from each other. According to an embodiment, at least one lowermost first material layer 31 may have a greater thickness than the other first material layers 31. Each of the second material layers 32 may have the same or different thicknesses in comparison with each other. According to an embodiment, at least one uppermost second material layer 32 may have a greater thickness than the other second material layers 32.

The conductive layer 33 may be formed on the stacked structure ST. The conductive layer 33 may be a gate electrode of a select transistor, or a select line. The conductive layer 33 may include a conductive material such as polysilicon, tungsten, or molybdenum. The sacrificial layer 34 may be formed on the conductive layer 33. The sacrificial layer 34 may include a nitride layer, a carbon layer, an amorphous carbon layer, or the like. The sacrificial layer 34 may serve as a hard mask during subsequent processes.

The first openings OP1 may be formed through the sacrificial layer 34, the conductive layer 33 and the stacked structure ST. The first openings OP1 may be arranged in the first direction I and in the second direction II crossing the first direction I.

Referring to FIGS. 2A, 2B and 2D, a memory layer M may be formed in the first openings OP1. The memory layer M may include at least one of a blocking layer 35, a data storage layer 36 and a tunnel insulating layer 37. The memory layer M may be formed along inner surfaces of the first openings OP1 and may be formed on the upper surface of the stacked structure ST. According to an embodiment, the blocking layer 35, the data storage layer 36 and the tunnel insulating layer 37 may be formed in a sequential manner. A buffer layer (not shown) may be formed before the memory layer M is formed. The buffer layer may serve to protect the memory layer M when removing the first material layers 31 during subsequent processes. The buffer layer may include nitride.

Subsequently, a channel layer 38 may be formed in the first openings OP1. The channel layer 38 may include a semiconductor material such as silicon or germanium, or may include a nanostructure. The channel layer 38 may be formed along the surface of the memory layer M. Subsequently, an insulating core 39 may be formed in the first openings OP1. The insulating core 39 may include an insulating material such as an oxide, a nitride, or air gaps.

Subsequently, referring to FIGS. 2A, 2B and 2E, a recess region may be formed by etching the insulating core 39. The recessed region may be provided to form a channel pad. An upper surface of an etched insulating core 39A may be located at a higher level than an upper surface of the conductive layer 33. An upper portion of the channel layer 38 may be exposed by the etched insulating core 39A. Subsequently, channel layers 38A may be formed by etching the channel layer 38. Tunnel insulating layers 37A may then be formed by etching the tunnel insulating layer 37. Upper surfaces of the tunnel insulating layers 37A may be located at substantially a same level as that of the insulating core 39. Upper surfaces of the channel layers 38A may protrude above the upper surface of the insulating core 39 or the upper surfaces of the tunnel insulating layers 37A.

Subsequently, channel pads 41 may be coupled to the channel layers 38A, respectively. According to an embodiment, after a conductive layer is formed, the channel pads 41 may be formed by planarizing the conductive layer until the upper surface of the sacrificial layer 34 is exposed. The planarization may be performed using a chemical mechanical polishing (CMP) process. When the conductive layer is planarized, portions of the blocking layer 35 and the data storage layer 36 that are formed on the upper surface of the stacked structure ST may also be planarized. As a result, blocking layers 35A and data storage layers 36A may be formed in the first openings OP1, respectively. The channel structure CH including the channel layer 38A and the channel pad 41 may be formed. The channel structure CH may further include the insulating core 39A. The channel layers 38A may protrude into the channel pads 41. The channel pads 41 may include a conductive material such as polysilicon, tungsten, or molybdenum.

The upper surfaces of the channel pads 41, the data storage layers 36A and the blocking layers 35A may be located at substantially the same or different levels in comparison with each other. Depending on etch rates of the channel pads 41, the data storage layers 36A and the blocking layers 35A, the upper surfaces thereof may be located at different levels in comparison with each other. A layer or a pad having a material with a lower etch rate may be less etched during planarization, such that an upper surface thereof may be located at a higher level. According to an embodiment, the upper surfaces of the channel pads 41 may be located at a higher level than those of the data storage layers 36A. The upper surfaces of the data storage layers 36A may be located at a higher level than those of the blocking layers 35A.

Subsequently, referring to FIGS. 2A, 2B and 2F, the sacrificial layer 34 may be removed. The sacrificial layer 34 may be removed using a dip-out process. As a result, the channel structure CH may protrude above the upper surface of the conductive layer 33, and the channel pads 41 may protrude above the upper surface of the conductive layer 33. In addition, the memory layer M surrounding the channel structure CH may be exposed.

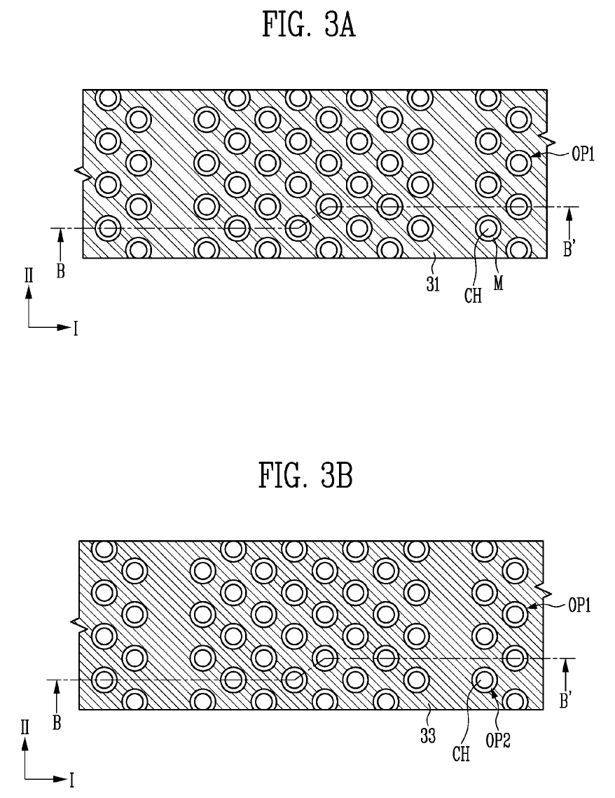

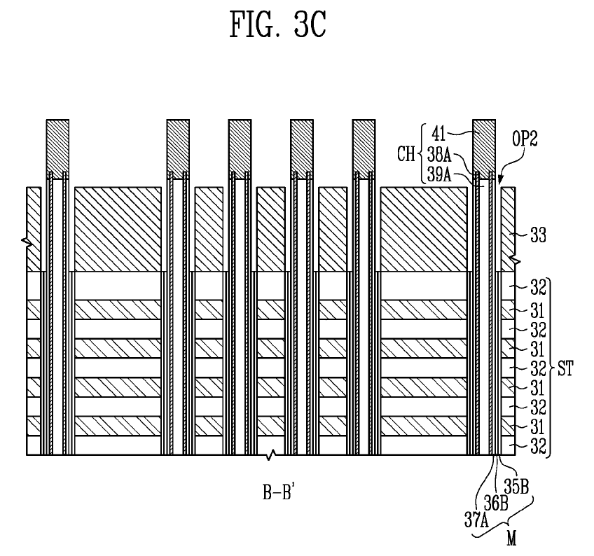

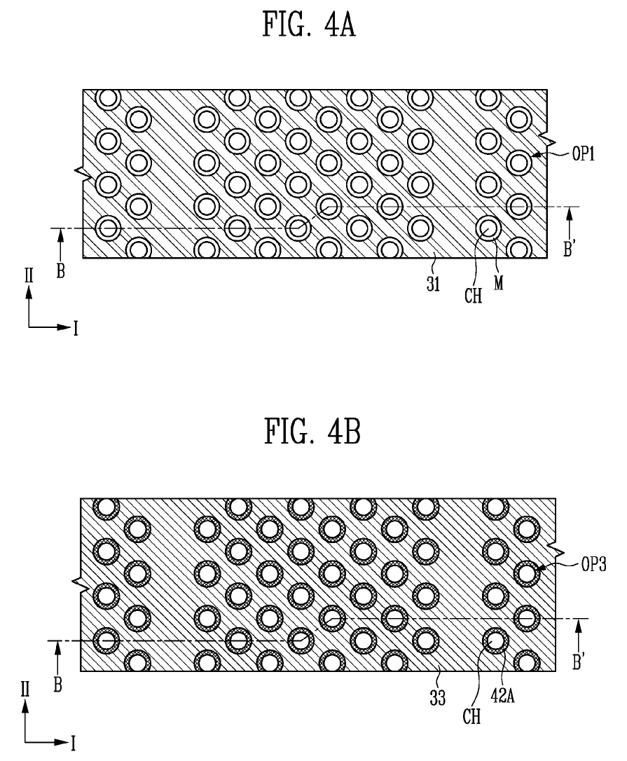

Referring to FIGS. 3A to 3C, the second openings OP2 may be formed between the channel structure CH and the conductive layer 33. The second openings OP2 may be formed by etching the memory layer M. Each of the second openings OP2 may have a ring shape surrounding each of the channel structures CH. According to an embodiment, blocking patterns 35B may be formed by selectively etching the blocking layers 35A. The blocking layers 35A may be etched using a dry cleaning process. Subsequently, data storage patterns 36B may be formed by selectively etching the data storage layers 36A. The data storage layers 36A may be etched using a dry cleaning process. The second openings OP2 may be formed at portions from which the blocking layers 35A and the data storage layers 36A are etched.

The data storage layers 36A and the blocking layers 35A may be etched to a depth to expose the uppermost second material layer 32. The data storage layers 36A and the blocking layers 35A may be etched to a depth wherein the uppermost first material layer 31 is not exposed. When the uppermost second material layer 32 has a greater thickness than the other second material layers 32, the uppermost second material layer 32 may prevent the uppermost first material layer 31 from being exposed when the data storage layers 36A and the blocking layers 35A are etched.

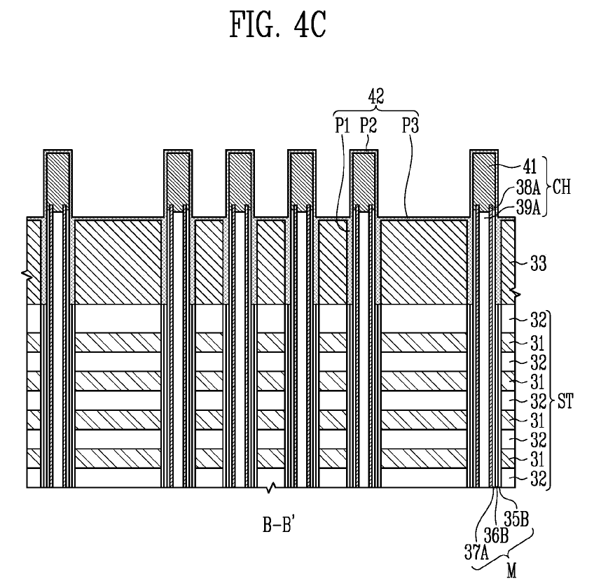

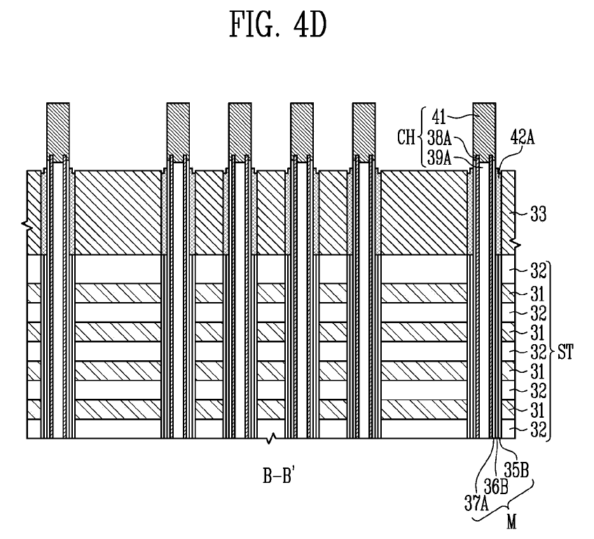

Referring to FIGS. 4A to 4D, conductive patterns 42A may be formed in the second openings OP2. First, referring to FIGS. 4A to 4C, a conductive material layer 42 may be formed on the conductive pads 41 and the upper surface of conductive material layer 33. The conductive material layer 42 may have the same or different materials than the materials of the conductive layer 33. The conductive material layer 42 may include a material having a lower specific resistance than that of the conductive layer 33. The conductive material layer 42 may include a conductive material such as polysilicon, doped polysilicon, a metal, a metal nitride, or a metal silicide. According to an embodiment, the conductive material layer 42 may include tungsten, tungsten nitride, tungsten silicide, titanium, titanium nitride, titanium silicide, tantalum, tantalum nitride, tantalum silicide, molybdenum, molybdenum nitride, molybdenum silicide, or a combination thereof.

The conductive material layer 42 may fill the second openings OP2 and surround the channel pads 41. The conductive material layer 42 may include a first portion P1 and a second portion P2. The first portion P1 may be formed in the second openings OP2. The second portion P2 may surround protruding portions of the channel structures CH. In addition, the conductive material layer 42 may include a third portion P3 that may be formed on the upper surface of the conductive layer 33. The conductive material layer 42 may be formed using a deposition process. During the deposition process, a seam may be formed in the conductive material layer 42. According to an embodiment, the seam may be formed at a position corresponding to the second portion P2, or at a position where the first portion P1 and the second portion P2 are coupled to each other.

Subsequently, an additional process may be performed with respect to materials of the conductive layer 33 and the conductive material layer 42. According to an embodiment, when the conductive layer 33 includes polysilicon and the conductive material layer 42 includes a metal, the conductive layer 33 may be silicided by performing heat treatment thereon.

Referring to FIGS. 4A, 4B and 4D, the conductive material layer 42 may be etched to form the conductive patterns 42A. By etching the second portion P2 of the conductive material layer 42, the conductive patterns 42A may be formed. The third portion P3 may also be etched when the second portion P2 is etched. The conductive material layer 42 may be formed using a dry cleaning process. As a result, the channel pads 41 and the conductive patterns 42A may be separated from each other. When a seam is exposed during the etching process of the conductive material layer 42, an etch rate of the corresponding portion may be increased compared to the other portions. As a result, the conductive patterns 42A may have irregular upper surfaces. For example, protrusions or recesses may be formed in the upper surfaces of the conductive patterns 42A.

The conductive patterns 42A may be interposed between the tunnel insulating layers 37A and the conductive layer 33, respectively. Each of the conductive patterns 42A may have a ring shape including a third opening OP3. The conductive patterns 42A may be electrically coupled to the conductive layer 33.

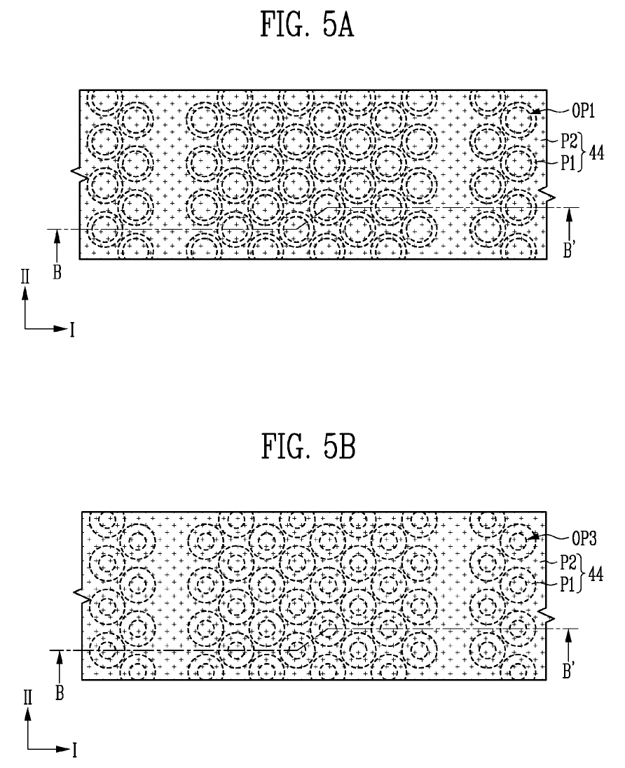

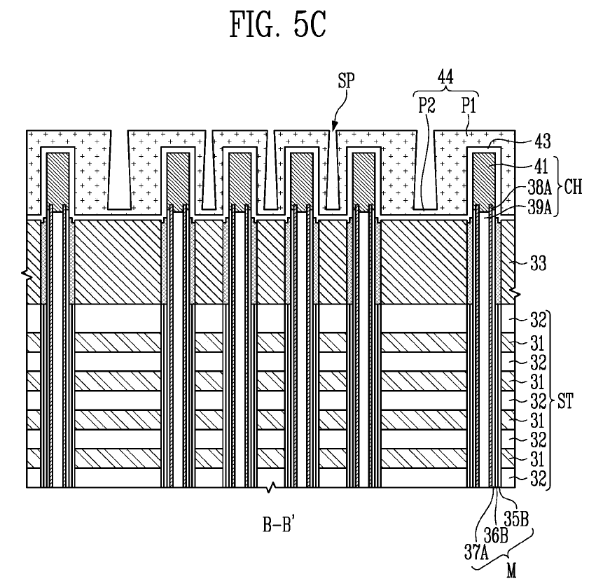

Referring to FIGS. 5A to 5C, an insulating protective layer 43 may be formed. The insulating protective layer 43 may surround the protruding portions of the channel structures CH. The insulating protective layer 43 may surround the exposed channel pads 41 and tunnel insulating layer 37A. The insulating protective layer 43 may surround the upper surface of the conductive layer 33. The insulating protective layer 43 may include an insulating material such as an oxide or a nitride. The insulating protective layer 43 may be formed using a deposition process and may be conformally formed along the profile of the channel pads 41.

Subsequently, a spacer material layer 44 may be formed over the insulating protective layer 43. The spacer material layer 44 may serve as an etch barrier during subsequent processes and include a material having a greater etch selectivity than the conductive layer 33. The spacer material layer 44 may include a carbon layer, an amorphous carbon layer, or the like.

The spacer material layer 44 may include first portions P1 surrounding the channel structures CH and a second portion P2 coupling the first portions P1. A space SP that is deposited with no spacer material may exist between the first portions P1. The first portions P1 may have a greater thickness than the second portion P2. Each of the first portions P1 may have an overhang structure so that an upper part thereof may be thicker than a lower part thereof. The spacer material layer 44 may be formed using a deposition process with poor step coverage. According to an embodiment, the spacer material layer 44 may be formed using Plasma Enhanced Chemical Vapor Deposition (PE-CVD), Physical Vapor Deposition (PVD), or the like.

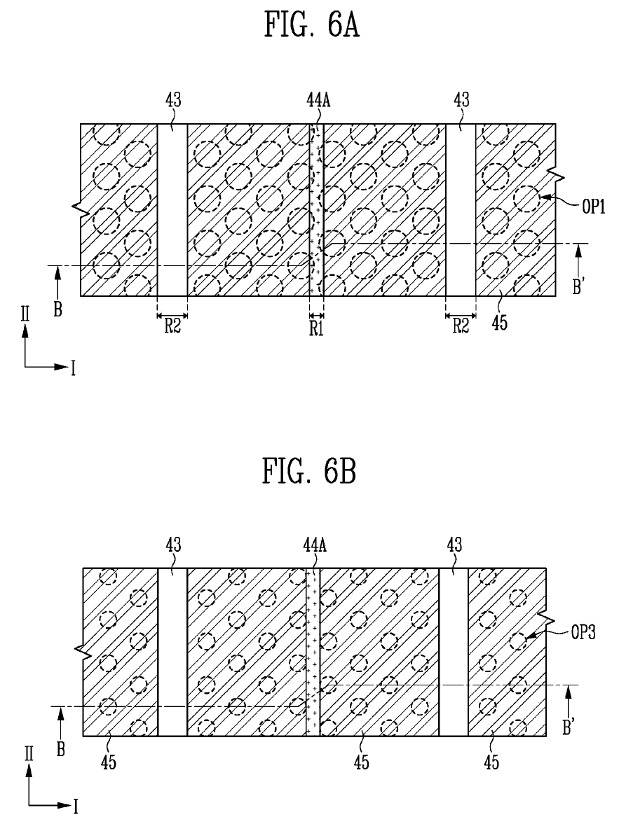

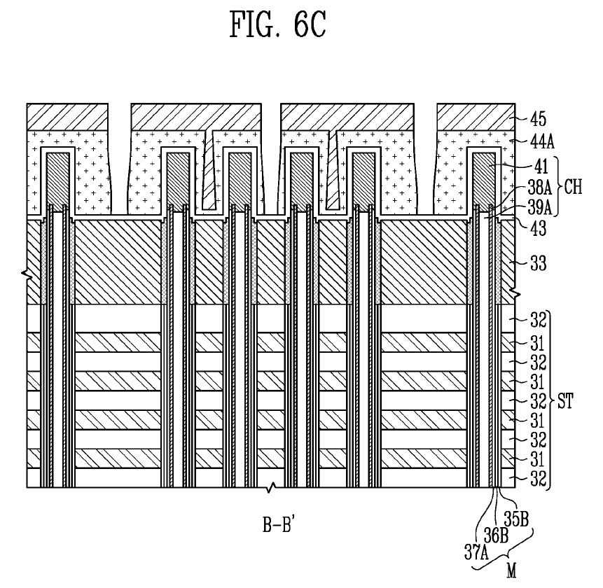

Referring to FIGS. 6A to 6C, a mask pattern 45 may be formed on the spacer material layer 44. The mask pattern 45 may include line patterns extending in the second direction II. The mask pattern 45 may cover the channel structures CH and expose a first region R1 where an isolation insulating pattern is formed and a second region R2 where a slit structure is formed.

By etching the spacer material layer 44 using the mask pattern 45 as an etch barrier, spacers 44A may be formed on the sidewalls of the channel structures CH. The second portion P2 of the spacer material layer 44 may be etched. An area of the first portion P1 that is thicker than the other areas may be etched from the upper part of the channel structure CH. As a result, the insulating protective layer 43 may be exposed.

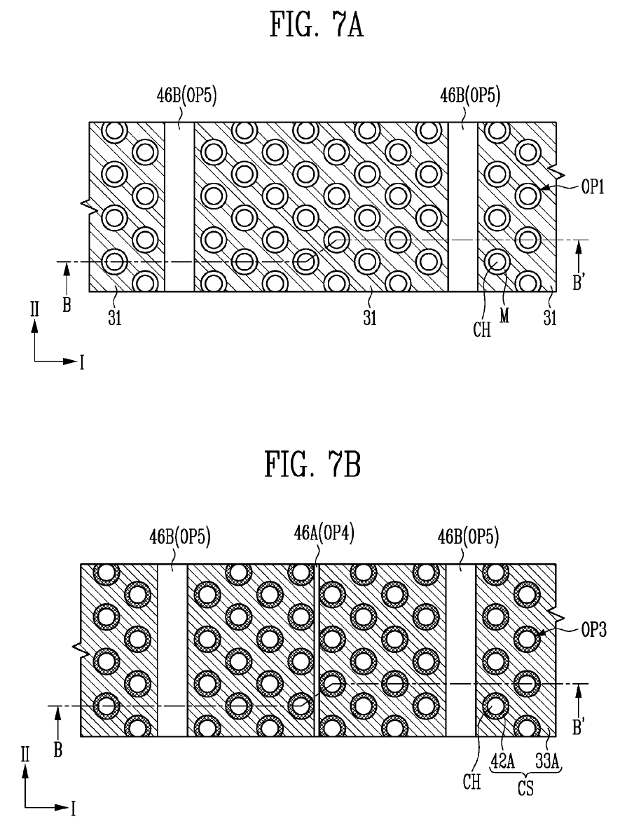

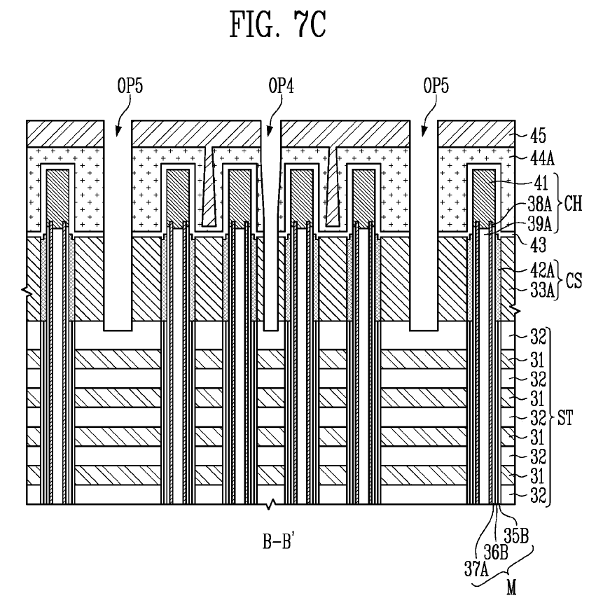

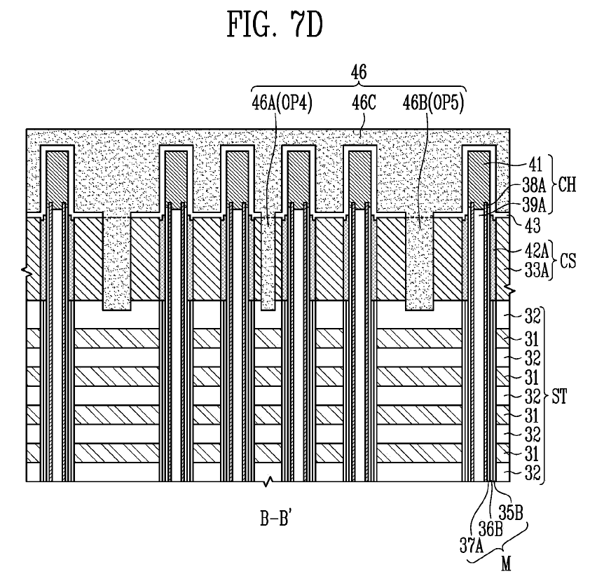

Referring to FIGS. 7A to 7D, fourth openings OP4 may be formed through the conductive layer 33 and isolation insulating patterns 46A may be formed in the fourth openings OP4. First, referring to FIGS. 7A to 7C, the insulating protective layer 43 and the conductive layer 33 may be etched using the mask pattern 45 and the spacers 44A as an etch barrier. According to an embodiment, under the condition that the conductive layer 33 has a high etch selectivity with respect to the spacers 44A, the conductive layer 33 may be selectively etched. As a result, the fourth opening OP4 and a fifth opening OP5 may be formed. The fourth opening OP4 and the fifth opening OP5 may pass through the conductive layer 33 and extend between the spacers 44A.

The fourth opening OP4 and the fifth opening OP5 may pass through the conductive layer 33 and have a depth which does not expose the uppermost first material layer 31. The fourth opening OP4 may be located at a portion corresponding to the first region R1. The fifth opening OP5 may be located at a portion corresponding to the second region R2. The fourth opening OP4 may have a smaller width than the fifth opening OP5.

The conductive patterns 42A may be exposed when the conductive layer 33 is etched. However, the conductive patterns 42A may be etched when the conductive layer 33 is etched. At least one of the conductive patterns 42A located adjacent to the first region R1 may be etched or exposed. As a result, conductive structures CS extending in the second direction II may be formed. Each of the conductive structures CS may include a conductive layer 33A and the conductive patterns 42A. Subsequently, the mask pattern 45 and the spacers 44A may be removed and a cleaning process may be performed.

Subsequently, referring to FIGS. 7A, 7B and 7D, an isolation insulating pattern 46A may be formed in the fourth opening OP4. When the isolation insulating pattern 46A is formed, a sacrificial pattern 46B may also be formed in the fifth opening OP5. When the isolation insulating pattern 46A is formed, an interlayer insulating layer 46C may also be formed. The isolation insulating pattern 46A, the sacrificial pattern 46B and the interlayer insulating layer 46C may be coupled into a single layer.

According to an embodiment, an insulating material layer may be formed on the conductive structure CS. The insulating material layer may be formed in the fourth opening OP4 and the fifth opening OP5 and may be formed on the insulating protective layer 43. After the insulating material layer is formed, a planarizing process may be performed thereon to thereby form an insulating layer 46. The insulating layer 46 may include the isolation insulating pattern 46A, the sacrificial pattern 46B and the interlayer insulating layer 46C.

However, the insulating layer 46 may be formed without removing the spacers 44A. The remaining spacers 44A may serve, together with the insulating layer 46, as an interlayer insulating layer.

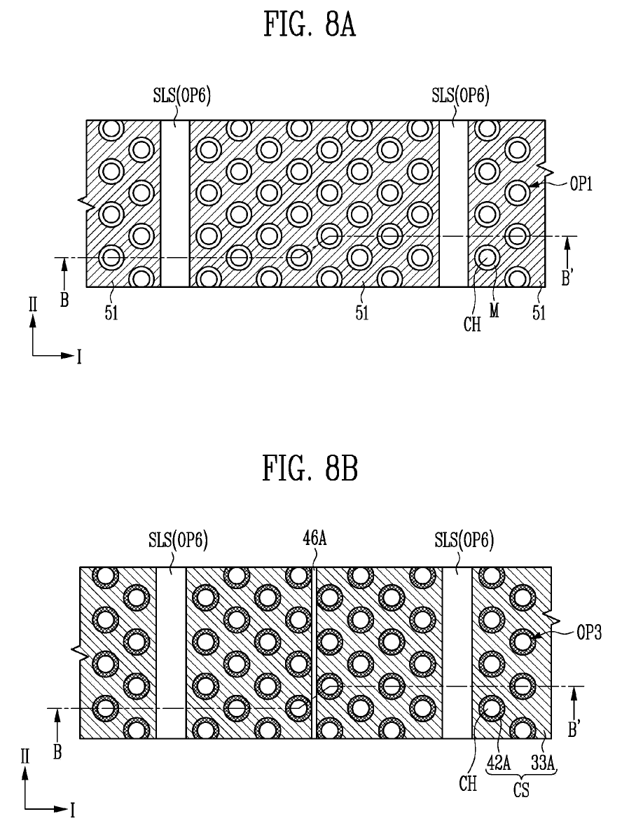

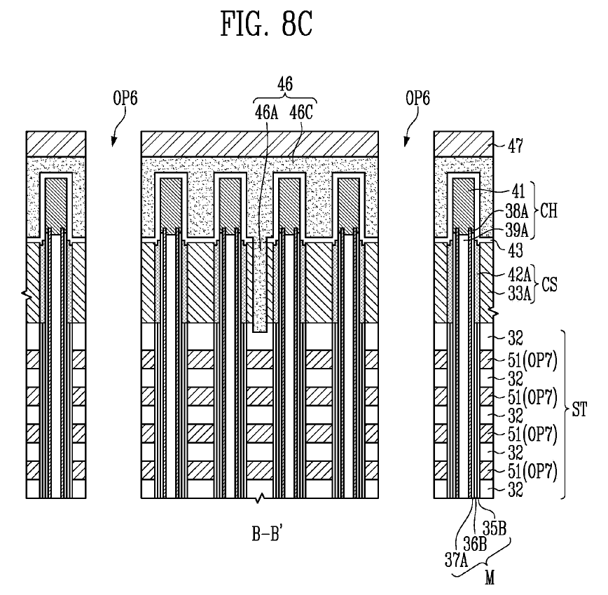

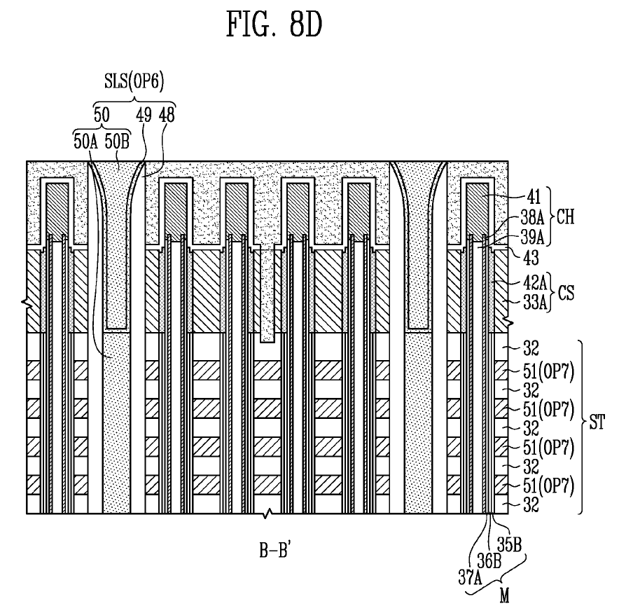

Referring to FIGS. 8A to 8D, the slit structure SLS may pass through the conductive structure CS and the stacked structure ST.

First, referring to FIGS. 8A to 8C, a mask pattern 47 may be formed on the insulating layer 46. The mask pattern 47 may be formed to expose the second region R2. Subsequently, the insulating layer 46 and the stacked structure ST may be etched using the mask pattern 47 as an etch barrier. As a result, a sixth opening OP6 may pass through the insulating layer 46, the conductive structure CS and the stacked structure ST. According to an embodiment, the sixth opening OP6 may have a depth such that the source structure located under the stacked structure ST is exposed.

Subsequently, seventh openings OP7 may be formed by removing the first material layers 31 through the sixth opening OP6. Third material layers 51 may be formed in the seventh openings OP7. According to an embodiment, the third material layers 51 may include a conductive material such as polysilicon, tungsten, molybdenum, or a metal. At least one lowermost third material layer 51, among the third material layers 51, may be a source select line, and the other third material layers 51 may be word lines.

Referring to FIGS. 8A, 8B and 8D, the slit structure SLS may be formed in the sixth opening OP6. After an insulating spacer 48 is formed in the sixth opening OP6, a source contact structure 50 may be formed in the insulating spacer 48. According to an embodiment, the source contact structure 50 may be formed in a single layer by filling the insulating spacer 48 with a conductive material layer. The single layer may include polysilicon. According to an embodiment, a first contact structure 50A, a barrier layer 49, and a second contact structure 50B may be formed in a sequential manner in the sixth opening OP6. The second contact structure 50B may include a material having a lower specific resistance than the first contact structure 50A.

According to the above-described manufacturing method, the spacers 44A be formed using the step difference between the upper surface of the conductive layer 33 and the upper surface of the channel structure CH. In addition, the conductive layer 33 may be etched using the spacers 44A and the mask pattern 45 as an etch barrier. Accordingly, by etching the conductive layer 33 by self-alignment, a region where the isolation insulating pattern 46A is formed may be defined. In addition, by replacing the data storage layer and the blocking layer with the conductive pattern 42A in a level corresponding to the conductive structure CS, a region where the isolation insulating pattern 46A is formed may be ensured, and a select transistor having a GAA structure may be formed.

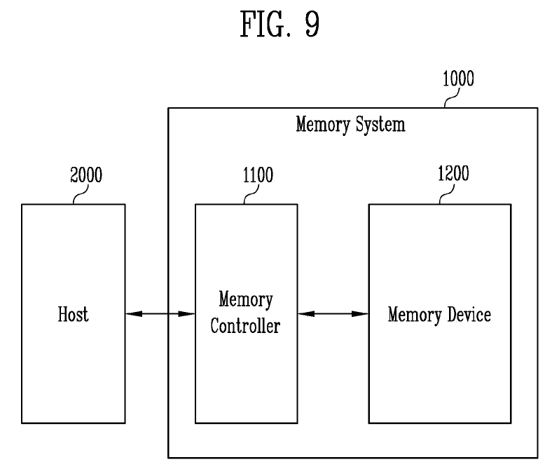

FIG. 9 is a block diagram illustrating a memory system 1000 according to an embodiment of the present disclosure.

Referring to FIG. 9, the memory system 1000 may include a memory device 1200 configured to store data and a controller 1100 configured to perform communications between the memory device 1200 and a host 2000.

The host 2000 may be a device or system configured to store data in the memory system 1000 or retrieve data from the memory system 1000. The host 2000 may generate requests for various operations and output the generated requests to the memory system 1000. The requests may include a program request for a program operation, a read request for a read operation, and an erase request for an erase operation. The host 2000 may communicate with the memory system 1000 by using at least one interface protocol among, for example, Peripheral Component Interconnect Express (PCIe), Advanced Technology Attachment (ATA), Serial ATA (SATA), Parallel ATA (PATA), Serial Attached SCSI (SAS), Non-Volatile Memory express (NVMe), Universal Serial Bus (USB), Multi-Media Card (MMC), Enhanced Small Disk Interface (ESDI), and Integrated Drive Electronics (IDE).

The host 2000 may include at least one of a computer, a portable digital device, a tablet, a digital camera, a digital audio player, a television, a wireless communication device, or a cellular phone. However, embodiments of the disclosed technology are not limited thereto.

The controller 1100 may control overall operations of the memory system 1000. The controller 1100 may control the memory device 1200 in response to the requests of the host 2000. The controller 1100 may control the memory device 1200 to perform a program operation, a read operation and an erase operation at the request of the host 2000. Alternatively, the controller 1100 may perform a background operation for performance improvement of the memory system 1000 in the absence of the request from the host 2000.

To control the operations of the memory device 1200, the controller 1100 may transfer a control signal and a data signal to the memory device 1200. The control signal and the data signal may be transferred to the memory device 1200 through different input/output lines. The data signal may include a command, an address, or data. The control signal may be used to differentiate periods wherein the data signal is input.

The memory device 1200 may perform a program operation, a read operation and an erase operation in response to control of the controller 1100. The memory device 1200 may be a volatile memory that loses data when a power supply is blocked, or a non-volatile memory that retains data in the absence of power supply. The memory device 1200 may have the structure as described above with reference to FIGS. 1A to 1E. In addition, the memory device 1200 may be the semiconductor device manufactured by the method as described above with reference to FIGS. 2A to 8D. According to an embodiment, the semiconductor memory device may include a stacked structure that includes first conductive layers and insulating layers stacked alternately with each other; second conductive layers located on the stacked structure, first openings passing through the second conductive layers and the stacked structure and having a first width; second conductive patterns formed in the first openings and located on the stacked structure to be electrically coupled to the second conductive layers; data storage patterns formed in the first openings and located under the second conductive patterns; and channel layers formed in the data storage patterns and the second conductive patterns.

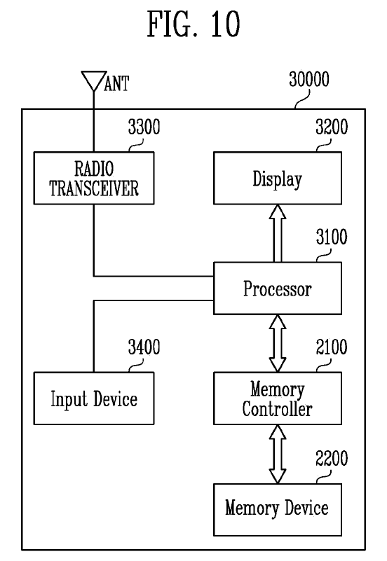

FIG. 10 is a block diagram illustrating a memory system 30000 according to an embodiment of the present disclosure.

Referring to FIG. 10, the memory system 30000 may be incorporated into a cellular phone, a smart phone, a tablet, a personal computer (PC), a personal digital assistant (PDA), or a wireless communication device. The memory system 30000 may include a memory device 2200 and a memory controller 2100 controlling the operations of the memory device 2200.

The memory controller 2100 may control a data access operation of the memory device 2200, for example, a program operation, an erase operation or a read operation of the memory device 2200 in response to control of a processor 3100.

The data programmed into the memory device 2200 may be output through a display 3200 in response to control of the memory controller 2100.

A radio transceiver 3300 may exchange a radio signal through an antenna ANT. For example, the radio transceiver 3300 may change the radio signal received through the antenna ANT into a signal which may be processed by the processor 3100. Therefore, the processor 3100 may process the signal output from the radio transceiver 3300 and transfer the processed signal to the memory controller 2100 or the display 3200. The memory controller 2100 may transfer the signal processed by the processor 3100 into the memory device 2200. In addition, the radio transceiver 3300 may change a signal output from the processor 3100 into a radio signal and output the radio signal to an external device through the antenna ANT. A control signal for controlling the operations of the host or data to be processed by the processor 3100 may be input by an input device 3400, and the input device 3400 may include a pointing device, such as a touch pad and a computer mouse, a keypad, or a keyboard. The processor 3100 may control the operations of the display 3200 so that data output from the memory controller 2100, data output from the radio transceiver 3300, or data output from an input device 3400 may be output through the display 3200.

According to an embodiment, the memory controller 2100 capable of controlling the operations of the memory device 2200 may be realized as a portion of the processor 3100, or as a separate chip from the processor 3100.

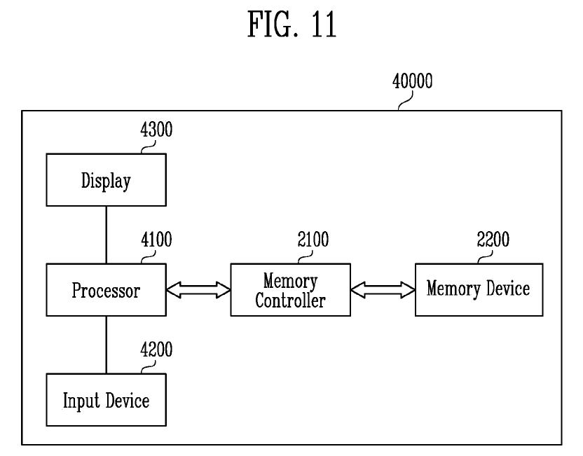

FIG. 11 is a block diagram illustrating a memory system 40000 according to an embodiment of the present disclosure.

Referring to FIG. 11, the memory system 40000 may be incorporated into a personal computer (PC), a tablet PC, a net-book, an e-reader, a personal digital assistant (PDA), a portable multimedia player (PMP), an MP3 player, or an MP4 player.

The memory system 40000 may include the memory device 2200 and the memory controller 2100 that controls a data processing operation of the memory device 2200.

A processor 4100 may output data stored in the memory device 2200 through a display 4300 according to data input through an input device 4200. Examples of the input device 4200 may include a pointing device such as a touch pad or a computer mouse, a keypad, or a keyboard.

The processor 4100 may control overall operations of the memory system 40000 and control operations of the memory controller 2100. According to an embodiment, the memory controller 2100 capable of controlling the operations of the memory device 2200 may be realized as a portion of the processor 4100, or as a separate chip from the processor 4100.

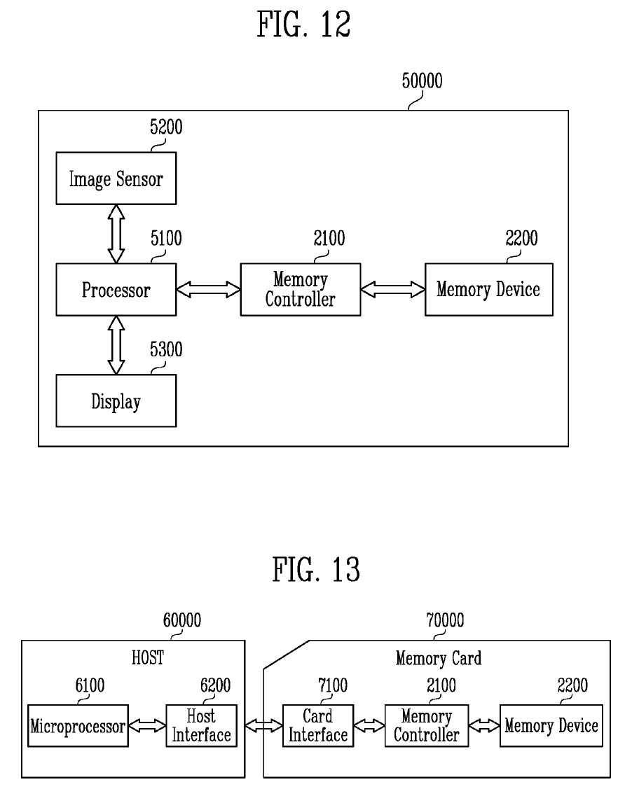

FIG. 12 is a block diagram illustrating a memory system 50000 according to an embodiment of the present disclosure.

Referring to FIG. 12, the memory system 50000 may be incorporated into an image processor, for example, a digital camera, a cellular phone with a digital camera attached thereto, a smart phone with a digital camera attached thereto, or a table PC with a digital camera attached thereto.

The memory system 50000 may include the memory device 2200 and the memory controller 2100 that controls a data processing operation of the memory device 2200, for example, a program operation, an erase operation, or a read operation.

An image sensor 5200 of the memory system 50000 may convert an optical image into digital signals. The converted digital signals may be transferred to a processor 5100 or the memory controller 2100. In response to control of the processor 5100, the converted digital signals may be output through a display 5300 or stored in the memory device 2200 through the memory controller 2100. In addition, the data stored in the memory device 2200 may be output through the display 5300 in response to control of the processor 5100 or the memory controller 2100.

According to an embodiment, the memory controller 2100 capable of controlling the operations of the memory device 2200 may be formed as a part of the processor 5100, or a separate chip from the processor 5100.

FIG. 13 is a block diagram illustrating a memory system 70000 according to an embodiment of the present disclosure.

Referring to FIG. 13, the memory system 70000 may include a memory card or a smart card. The memory system 70000 may include the memory device 2200, the memory controller 2100, and a card interface 7100.

The memory controller 2100 may control data exchange between the memory device 2200 and the card interface 7100. According to an embodiment, the card interface 7100 may be, but is not limited thereto, a secure digital (SD) card interface or a multi-media card (MMC) interface.

The card interface 7100 may interface data exchange between a host 60000 and the memory controller 2100 according to a protocol of the host 60000. According to an embodiment, the card interface 7100 may support a Universal Serial Bus (USB) protocol and an InterChip (IC)-USB protocol. The card interface 7100 may refer to hardware capable of supporting a protocol which is used by the host 60000, software installed in the hardware, or a signal transmission method.

When the memory system 70000 is connected to a host interface 6200 of the host 60000 such as a PC, a tablet PC, a digital camera, a digital audio player, a cellular phone, a console video game hardware, or a digital set-top box, the host interface 6200 may perform data communication with the memory device 2200 through the card interface 7100 and the memory controller 2100 in response to control of a microprocessor 6100.

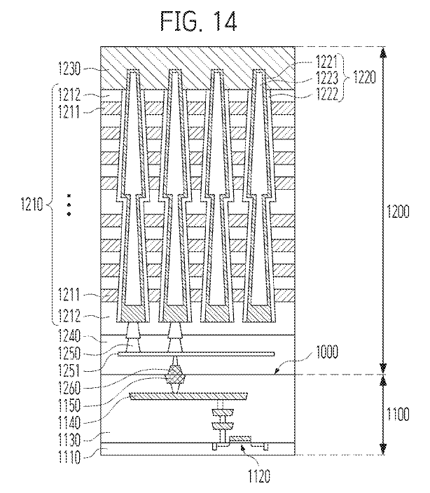

FIG. 14 is a diagram illustrating the structure of a semiconductor device in accordance with an embodiment.

Referring to FIG. 14, the semiconductor device may include a first semiconductor structure 1100 and a second semiconductor structure 1200. A bonding interface 1000 may be located in the semiconductor device, and the first semiconductor structure 1100 is distinguished from the second semiconductor structure 1200 by the bonding interface 1000. The second semiconductor structure 1200 may be disposed over or under the first semiconductor structure 1100. The first semiconductor structure 1100 may include a peripheral circuit, and the second semiconductor structure 1200 may include a memory cell array.

The first semiconductor structure 1100 may include a substrate 1110, a transistor 1120, a first interlayer insulating layer 1130, a first interconnection structure 1140, and a first bonding pad 1150. The transistor 1120 may be included in the peripheral circuit. The peripheral circuit may include a row decoder, a page buffer, an input/output circuit, a logic circuit, and the like. The first interconnection structure 1140 may be disposed in the first interlayer insulating layer 1130 and may include a via, a wiring line, and the like. The first bonding pad 1150 may be disposed at the bonding interface 1000 and may be electrically connected to the peripheral circuit through the first interconnection structure 1140.

The second semiconductor structure 1200 may include a gate structure 1210, a channel structure 1220, a source structure 1230, a second interlayer insulating layer 1240, a second interconnection structure 1250, and a second bonding pad 1260. The gate structure 1210 may include gate lines 1211 alternately stacked with insulating layers 1212. The source structure 1230 may be disposed over the gate structure 1210. The channel structure 1220 may include a channel layer 1221, a memory layer 1222, and/or an insulating core 1223. The channel layer 1221 may extend through the gate structure 1210 and may be connected to the source structure 1230. The second interconnection structure 1250 may be disposed in the second interlayer insulating layer 1240 and may include a via, a wiring line, and the like. For example, the second interconnection structure 1250 may include a bitline 1251. The second bonding pad 1260 may be disposed at the bonding interface 1000 and may be electrically connected to the memory cell array through the second interconnection structure 1250.

The first bonding pad 1150 may be electrically connected to the second bonding pad 1260 at the bonding interface 1000, and the memory cell array may be electrically connected to the peripheral circuit through the first bonding pad 1150 and the second bonding pad 1260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

Some of the first semiconductor structure 1100 and the second semiconductor structure 1200 may be formed after the first wafer is bonded to the second wafer. For example, the second wafer including a substrate, the gate structure 1210, and the channel structure 1220 may be formed, flipped, and bonded to the first wafer including the transistor 1120. Subsequently, a rear surface of the gate structure 1210 may be exposed by removing the substrate of the second wafer, and the channel layer 1221 may be exposed by etching the memory layer 1222 of the channel structure 1220 protruding from the rear surface of the gate structure 1210. The source structure 1230 may be formed on the rear surface of the gate structure 1210.

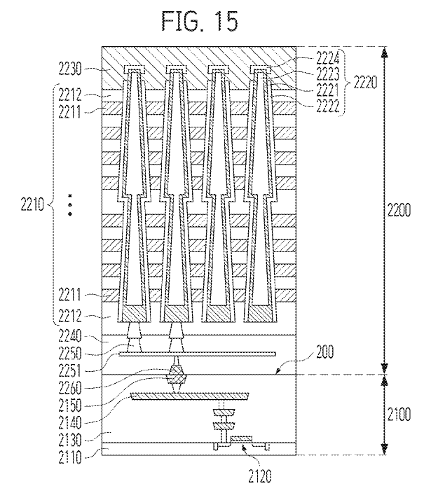

FIG. 15 is a diagram illustrating the structure of a semiconductor device in accordance with an embodiment.

Referring to FIG. 15, the semiconductor device may include a first semiconductor structure 2100 and a second semiconductor structure 2200. A bonding interface 2000 may be located in the semiconductor device, and the first semiconductor structure 2100 may be distinguished from the second semiconductor structure 2200 by the bonding interface 2000. The second semiconductor structure 2200 may be disposed over or under the first semiconductor structure 2100. The first semiconductor structure 2100 may include a peripheral circuit, and the second semiconductor structure 2200 may include a memory cell array.

The first semiconductor structure 2100 may include a substrate 2110, a transistor 2120, a first interlayer insulating layer 2130, a first interconnection structure 2140, and a first bonding pad 2150. The transistor 2120 may be included in the peripheral circuit. The peripheral circuit may include a row decoder, a page buffer, an input/output circuit, a logic circuit, and the like. The first interconnection structure 2140 may be disposed in the first interlayer insulating layer 2130 and may include a via, a wiring line, and the like. The first bonding pad 2150 may be disposed at the bonding interface 2000 and may be electrically connected to the peripheral circuit through the first interconnection structure 2140.

The second semiconductor structure 2200 may include a gate structure 2210, a channel structure 2220, a source structure 2230, a second interlayer insulating layer 2240, a second interconnection structure 2250, and a second bonding pad 2260. The gate structure 2210 may include gate lines 2211 alternately stacked with insulating layers 2212. The source structure 2230 may be disposed over the gate structure 2210. The channel structure 2220 may include a channel layer 2221, a memory layer 2222, an insulating core 2223, and/or a memory pattern 2224. The channel layer 2221 may extend through the gate structure 2210 and may be connected to the source structure 2230. The second interconnection structure 2250 may be disposed in the second interlayer insulating layer 2240 and may include a via, a wiring line, and the like. For example, the second interconnection structure 2250 may include a bitline 2251. The second bonding pad 2260 may be disposed at the bonding interface 2000 and may be electrically connected to the memory cell array through the second interconnection structure 2250.

The first bonding pad 2150 may be electrically connected to the second bonding pad 2260 at the bonding interface 2000, and the memory cell array may be electrically connected to the peripheral circuit through the first bonding pad 2150 and the second bonding pad 2260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 2230 may be connected to the channel layer 2221 using a source sacrificial layer. For example, the channel structure 2220 may be formed to protrude into a source structure including the source sacrificial layer. An opening exposing the channel structure 2220 may be formed by removing the source sacrificial layer, and the channel layer 2221 may be exposed by etching the memory layer 2222 through the opening. A source layer connected to the channel layer 2221 may be formed in the opening to form the source structure 2230 including the source layer. The second wafer including the source structure 2230 may be flipped and bonded to the first wafer including the transistor 2120.

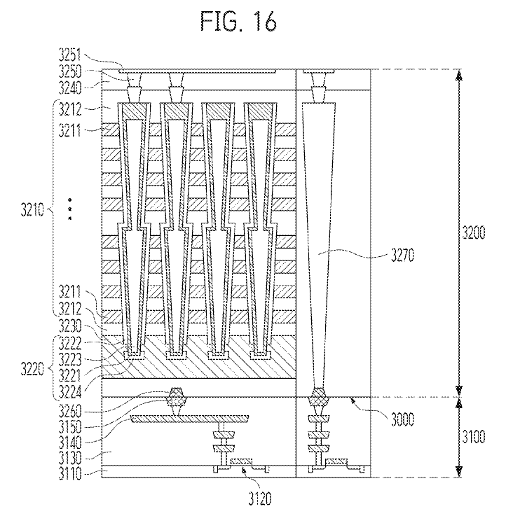

FIG. 16 is a diagram illustrating the structure of a semiconductor device in accordance with an embodiment.

Referring to FIG. 16, the semiconductor device may include a first semiconductor structure 3100 and a second semiconductor structure 3200. A bonding interface 3000 may be located in the semiconductor device, and the first semiconductor structure 3100 may be distinguished from the second semiconductor structure 3200 by the bonding interface 3000. The second semiconductor structure 3200 may be disposed over or under the first semiconductor structure 3100. The first semiconductor structure 3100 may include a peripheral circuit, and the second semiconductor structure 3200 may include a memory cell array.

The first semiconductor structure 3100 may include a substrate 3110, a transistor 3120, a first interlayer insulating layer 3130, a first interconnection structure 3140, and a first bonding pad 3150. The transistor 3120 may be included in the peripheral circuit. The peripheral circuit may include a row decoder, a page buffer, an input/output circuit, a logic circuit, and the like. The first interconnection structure 3140 may be disposed in the first interlayer insulating layer 3130 and may include a via, a wiring line, and the like. The first bonding pad 3150 may be disposed at the bonding interface 3000 and may be electrically connected to the peripheral circuit through the first interconnection structure 3140.

The second semiconductor structure 3200 may include a gate structure 3210, a channel structure 3220, a source structure 3230, a second interlayer insulating layer 3240, a second interconnection structure 3250, a second bonding pad 3260, and a contact plug 3270. The gate structure 3210 may include gate lines 3211 alternately stacked with insulating layers 3212. The source structure 3230 may be disposed below the gate structure 3210. The channel structure 3220 may include a channel layer 3221, a memory layer 3222, an insulating core 3223, and/or a memory pattern 3224. The channel layer 3221 may extend through the gate structure 3210, and may be connected to the source structure 3230. The second interconnection structure 3250 may be disposed in the second interlayer insulating layer 3240 and may include a via, a wiring line, and the like. For example, the second interconnection structure 3250 may include a bitline 3251. The second bonding pad 3260 may be disposed at the bonding interface 3000 and may be electrically connected to the memory cell array through the second interconnection structure 3250.

The first bonding pad 3150 may be electrically connected to the second bonding pad 3260 at the bonding interface 3000, and the memory cell array may be electrically connected to the peripheral circuit through the first bonding pad 3150 and the second bonding pad 3260. The contact plug 3270 may extend through the second interlayer insulating layer 3240 or a dummy stack and may be connected to the peripheral circuit through the first bonding pad 3150 and the second bonding pad 3260.

The semiconductor device may be manufactured using a method such as hybrid bonding, metal bonding, insulator bonding, or semiconductor bonding. For example, the semiconductor device may be manufactured by manufacturing a first wafer including the peripheral circuit and a second wafer including the memory cell array, and bonding the first wafer to the second wafer.

When the second wafer is manufactured, the source structure 3230 may be connected to the channel layer 3221 using a source sacrificial layer. For example, the channel structure 3220 protrudes into a source structure including the source sacrificial layer. Subsequently, an opening exposing the channel structure 3220 may be formed by removing the source sacrificial layer, and the channel layer 3221 may be exposed by etching the memory layer 3222 through the opening. A source layer connected to the channel layer 3221 may be formed in the opening to form the source structure 3230 including the source layer. The second wafer including the source structure 3230 may be bonded to the first wafer including the transistor 3120. In this example, the second wafer may be bonded to the first wafer in an un-flipped state. An interconnection structure such as a through silicon via (TSV) may be formed.

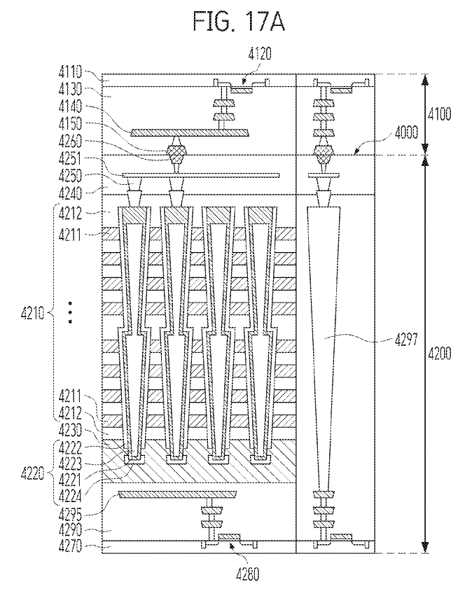

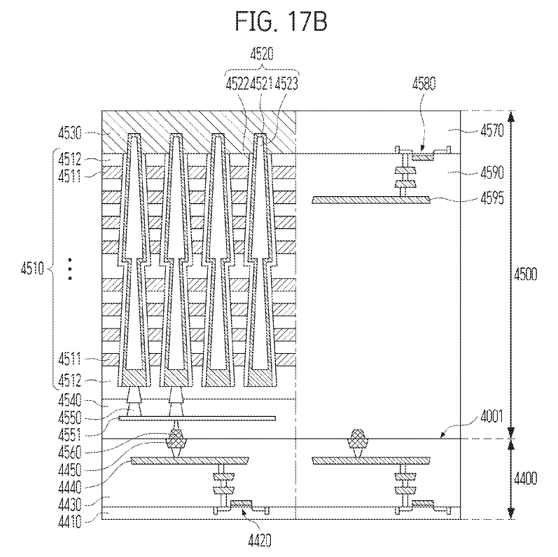

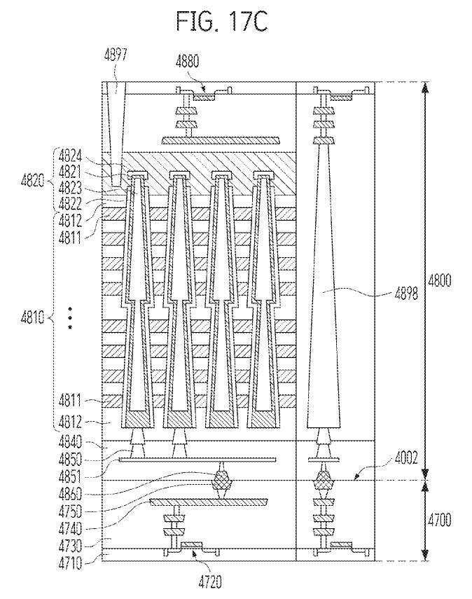

FIG. 17A is a diagram illustrating the structure of a semiconductor device in accordance with an embodiment.

Referring to FIG. 17A, the semiconductor device may include a first semiconductor structure 4100 and a second semiconductor structure 4200. A bonding interface 4000 may be located in the semiconductor device, and the first semiconductor structure 4100 may be distinguished from the second semiconductor structure 4200 by the bonding interface 4000. The second semiconductor structure 4200 may be disposed over or under the first semiconductor structure 4100. A peripheral circuit may include a first peripheral circuit and a second peripheral circuit. The first peripheral circuit and the second peripheral circuit may be distributed and disposed in the first semiconductor structure 4100 and the second semiconductor structure 4200. The first semiconductor structure 4100 may include the first peripheral circuit, and the second semiconductor structure 4200 may include the second peripheral circuit and a memory cell array.

The first semiconductor structure 4100 may include a first substrate 4110, a first transistor 4120, a first interlayer insulating layer 4130, a first interconnection structure 4140, and a first bonding pad 4150. The first transistor 4120 may be included in the first peripheral circuit. The first peripheral circuit may include a row decoder, a page buffer, an input/output circuit, a logic circuit, and the like. The first interconnection structure 4140 may be disposed in the first interlayer insulating layer 4130 and may include a via, a wiring line, and the like. The first bonding pad 4150 may be disposed at the bonding interface 4000 and may be electrically connected to the first peripheral circuit through the first interconnection structure 4140.

The second semiconductor structure 4200 may include a gate structure 4210, a channel structure 4220, a source structure 4230, a second interlayer insulating layer 4240, a second interconnection structure 4250, a second bonding pad 4260, a second substrate 4270, a second transistor 4280, a third interlayer insulating layer 4290, a third interconnection structure 4295, and a contact plug 4297.

The second transistor 4280 may be disposed on the second substrate 4270. The second transistor 4280 may be included in the second peripheral circuit. The second peripheral circuit may include a row decoder, a page buffer, an input/output circuit, a logic circuit, and the like. The third interconnection structure 4295 may be formed in the third interlayer insulating layer 4290 and may include a via, a wiring line, and the like. The third interconnection structure 4295 may be electrically connected to the second peripheral circuit.

The gate structure 4210 may be disposed over the second peripheral circuit. The gate structure 4210 may include gate lines 4211 alternately stacked with insulating layers 4212. The source structure 4230 may be disposed under the gate structure 4210. The channel structure 4220 may include a channel layer 4221, a memory layer 4222, an insulating core 4223, and/or a memory pattern 4224. The channel layer 4221 may extend through the gate structure 4210 and may be connected to the source structure 4230. The second interconnection structure 4250 may be disposed in the second interlayer insulating layer 4240 and may include a via, a wiring line, and the like. For example, the second interconnection structure 4250 may include a bitline 4251. The second bonding pad 4260 may be disposed at the bonding interface 4000 and may be electrically connected to the memory cell array through the second interconnection structure 4250.

The first bonding pad 4150 may be electrically connected to the second bonding pad 4260 at the bonding interface 4000, and the memory cell array may be electrically connected to the first peripheral circuit through the first bonding pad 4150 and the second bonding pad 4260. The contact plug 4297 may extend through the second interlayer insulating layer 4240 or a dummy stack. The first peripheral circuit may be connected to the second peripheral circuit through the contact plug 4297, the first bonding pad 4150 and the second bonding pad 4260.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

When the second wafer is manufactured, the source structure 4230 may be connected to the channel layer 4221 using a source sacrificial layer. For example, the second peripheral circuit may be formed on the second substrate 4270, and a source structure including the source sacrificial layer and the channel structure 4220 protruding into the source structure may be formed over the second peripheral circuit. An opening exposing the channel structure 4220 may be formed by removing the source sacrificial layer, and the channel layer 4221 may be exposed by etching the memory layer 4222 through the opening. A source layer connected to the channel layer 4221 may be formed in the opening to form the source structure 4230 including the source layer. The second wafer including the second peripheral circuit and the source structure 4230 may be bonded to the first wafer including the first peripheral circuit.

FIG. 17B is a diagram illustrating the structure of a semiconductor device in accordance with an embodiment.

Referring to FIG. 17B, the semiconductor device may include a first semiconductor structure 4400 and a second semiconductor structure 4500. A bonding interface 4001 may be located in the semiconductor device, and the first semiconductor structure 4400 may be distinguished from the second semiconductor structure 4500 by the bonding interface 4001. The second semiconductor structure 4500 may be disposed over or under the first semiconductor structure 4400. A peripheral circuit may include a first peripheral circuit and a second peripheral circuit. The first peripheral circuit and the second peripheral circuit may be distributed and disposed in the first semiconductor structure 4400 and the second semiconductor structure 4500. The first semiconductor structure 4400 may include the first peripheral circuit, and the second semiconductor structure 4500 may include the second peripheral circuit and a memory cell array.

The first semiconductor structure 4400 may include a first substrate 4410, a first transistor 4420, a first interlayer insulating layer 4430, a first interconnection structure 4440, and a first bonding pad 4450. The first transistor 4420 may be included in the first peripheral circuit. The first peripheral circuit may include a row decoder, a page buffer, an input/output circuit, a logic circuit, and the like. The first interconnection structure 4440 may be disposed in the first interlayer insulating layer 4430 and may include a via, a wiring line, and the like. The first interconnection structure 4440 may be electrically connected to the first peripheral circuit.

The second semiconductor structure 4500 may include a gate structure 4510, a channel structure 4520, a source structure 4530, a second interlayer insulating layer 4540, a second interconnection structure 4550, a second bonding pad 4560, a second substrate 4570, a second transistor 4580, a third interlayer insulating layer 4590, and a third interconnection structure 4595.

The second transistor 4580 may be disposed on the second substrate 4570. The second transistor 4580 may be included in the second peripheral circuit. The third interconnection structure 4595 may be formed in the third interlayer insulating layer 4590 and may include a via, a wiring line, and the like. The third interconnection structure 4595 may be electrically connected to the second peripheral circuit.

The source structure 4530 may be disposed at a level corresponding to the second substrate 4570, and the gate structure 4510 may be disposed under the source structure 4530. The gate structure 4510 may include gate lines 4511 alternately stacked with insulating layers 4512. The channel structure 4520 may include a channel layer 4521, a memory layer 4522, and/or an insulating core 4523. The channel layer 4521 may extend through the gate structure 4510 and may be connected to the source structure 4530. The second interconnection structure 4550 may be disposed in the second interlayer insulating layer 4540 and may include a via, a wiring line, and the like. For example, the second interconnection structure 4550 may include a bitline 4551. The second bonding pad 4560 may be disposed at the bonding interface 4001, and may be electrically connected to the memory cell array through the second interconnection structure 4550.

The first bonding pad 4450 may be electrically connected to the second bonding pad 4560 at the bonding interface 4001, and the memory cell array may be electrically connected to the first peripheral circuit through the first bonding pad 4450 and the second bonding pad 4560.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4400 and the second semiconductor structure 4500 may be formed after the first wafer is bonded to the second wafer. For example, the second peripheral circuit may be formed in a peripheral region of the second substrate 4560, and the channel structure 4520 protruding into the second substrate 4570 may be formed in a cell region of the second substrate 4570. The second wafer including the second peripheral circuit and the source structure 4530 may be flipped and bonded to the first wafer including the first peripheral circuit. Subsequently, a rear surface of the gate structure 4510 may be exposed by removing the cell region of the second substrate 4570, and the channel layer 4521 may be exposed by etching the memory layer 4522 of the channel structure 4520 protruding from the rear surface of the gate structure 4510. The source structure 4530 may be formed on the rear surface of the gate structure 4510.

FIG. 17C is a diagram illustrating the structure of a semiconductor device in accordance with an embodiment.

Referring to FIG. 17C, the semiconductor device may include a first semiconductor structure 4700 and a second semiconductor structure 4800. A bonding interface 4002 may be located in the semiconductor device, and the first semiconductor structure 4700 may be distinguished from the second semiconductor structure 4800 by the bonding interface 4002. The second semiconductor structure 4800 may be disposed over or under the first semiconductor structure 4700. A peripheral circuit may include a first peripheral circuit and a second peripheral circuit. The first peripheral circuit and the second peripheral circuit may be distributed and disposed in the first semiconductor structure 4700 and the second semiconductor structure 4800. The first semiconductor structure 4700 may include the first peripheral circuit, and the second semiconductor structure 4800 may include the second peripheral circuit and a memory cell array.

The first semiconductor structure 4700 may include a first substrate 4710, a first transistor 4720, a first interlayer insulating layer 4730, a first interconnection structure 4740, and a first bonding pad 4750. The first transistor 4720 may be included in the first peripheral circuit. The first peripheral circuit may include a row decoder, a page buffer, an input/output circuit, a logic circuit, and the like. The first interconnection structure 4740 may be disposed in the first interlayer insulating layer 4730 and may include a via, a wiring line, and the like. The first bonding pad 4750 may be disposed at the bonding interface 4002 and may be electrically connected to the first peripheral circuit through the first interconnection structure 4740.

The second semiconductor structure 4800 may include a gate structure 4810, a channel structure 4820, a source structure 4830, a second interlayer insulating layer 4840, a second interconnection structure 4850, a second bonding pad 4860, a second substrate 4870, a second transistor 4880, a third interlayer insulating layer 4890, a third interconnection structure 4895, a through via 4897, and a contact plug 4898.

The second transistor 4880 may be disposed on the second substrate 4870. The second transistor 4880 may be included in the second peripheral circuit. The second peripheral circuit may include a row decoder, a page buffer, an input/output circuit, a logic circuit, and the like. The third interconnection structure 4895 may be formed in the third interlayer insulating layer 4890 and may include a via, a wiring line, and the like. The third interconnection structure 4895 may be electrically connected to the second peripheral circuit.

The source structure 4830 may be disposed under the second peripheral circuit. The through via 4897 may extend through the second substrate 4870 and the third interlayer insulating layer 4890 and may be connected to the source structure 4830. The gate structure 4810 may be disposed under the source structure 4830. The gate structure 4810 may include gate lines 4811 alternately stacked with insulating layers 4812. The channel structure 4820 may include a channel layer 4821, a memory layer 4822, an insulating core 4823, and/or a memory pattern 4824. The channel layer 4821 may extend through the gate structure 4810 and may be connected to the source structure 4830. The second interconnection structure 4850 may be disposed in the second interlayer insulating layer 4840 and may include a via, a wiring line, and the like. For example, the second interconnection structure 4850 may include a bitline 4851. The second bonding pad 4860 may be disposed at the bonding interface 4002 and may be electrically connected to the memory cell array through the second interconnection structure 4850.

The first bonding pad 4750 may be electrically connected to the second bonding pad 4860 at the bonding interface 4002, and the memory cell array may be electrically connected to the first peripheral circuit through the first bonding pad 4750 and the second bonding pad 4860. The contact plug 4898 may extend through the second interlayer insulating layer 4840 or a dummy stack. The first peripheral circuit may be connected to the second peripheral circuit through the contact plug 4898, the first bonding pad 4750 and the second bonding pad 4860.

The semiconductor device may be manufactured using a method such as hybrid bonding, metal bonding, insulator bonding, or semiconductor bonding. For example, the semiconductor device may be manufactured by manufacturing a first wafer including the first peripheral circuit and a second wafer including the second peripheral circuit and the memory cell array, and bonding the first wafer to the second wafer.

Some of the first semiconductor structure 4700 and the second semiconductor structure 4800 may be formed after the first wafer may be bonded to the second wafer. For example, the second wafer including the second substrate 4870, the second peripheral circuit, and a source structure including a source sacrificial layer may be formed. The second wafer may be flipped and bonded to the first wafer including the first peripheral circuit. Subsequently, a through hole extending through the second substrate 4870 and the third interlayer insulating layer 4890 to expose the source sacrificial layer may be formed, and an opening, through which the channel structure 4820 is exposed, may be formed by removing the source sacrificial layer through the through hole. The channel layer 4821 may be exposed by etching the memory layer 4822 through the opening, and a source layer connected to the channel layer 4821 may be formed in the opening to form the source structure 4830 including the source layer. The through via 4897 may be formed in the through hole.

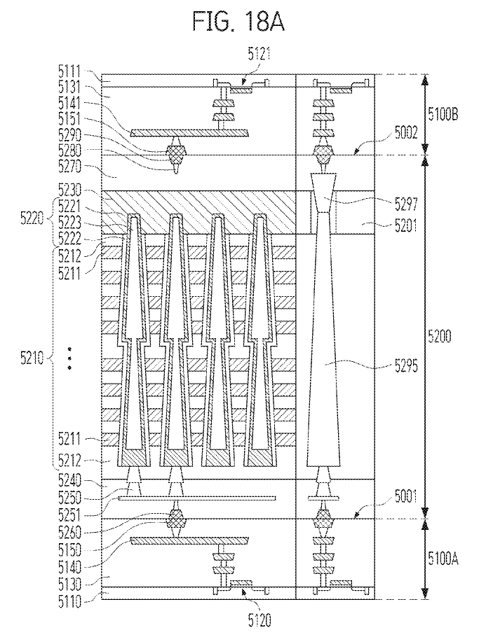

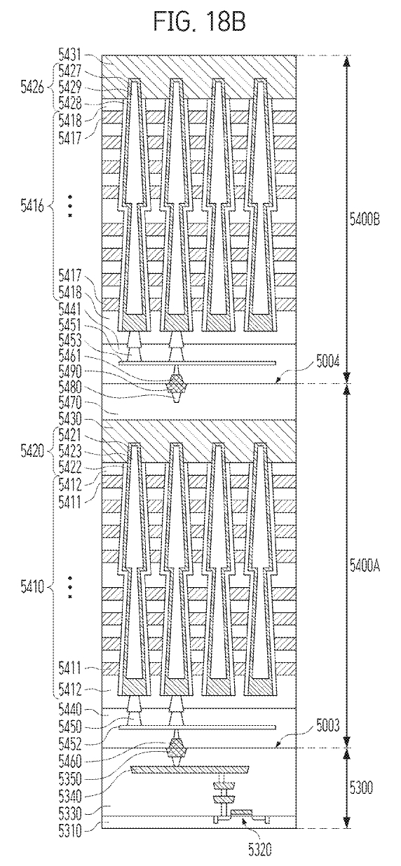

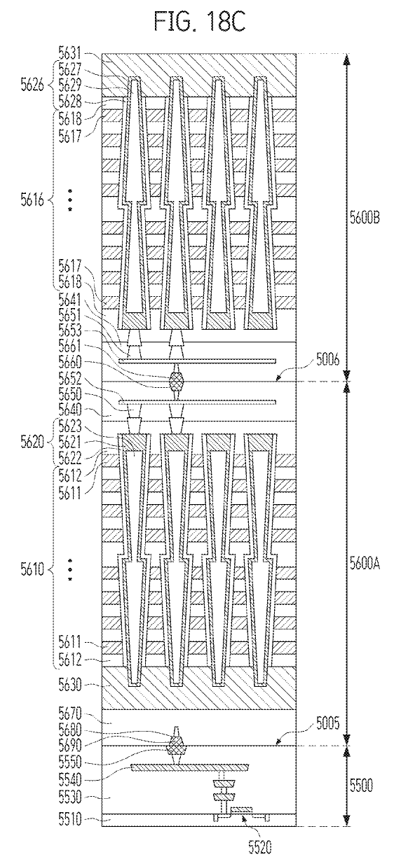

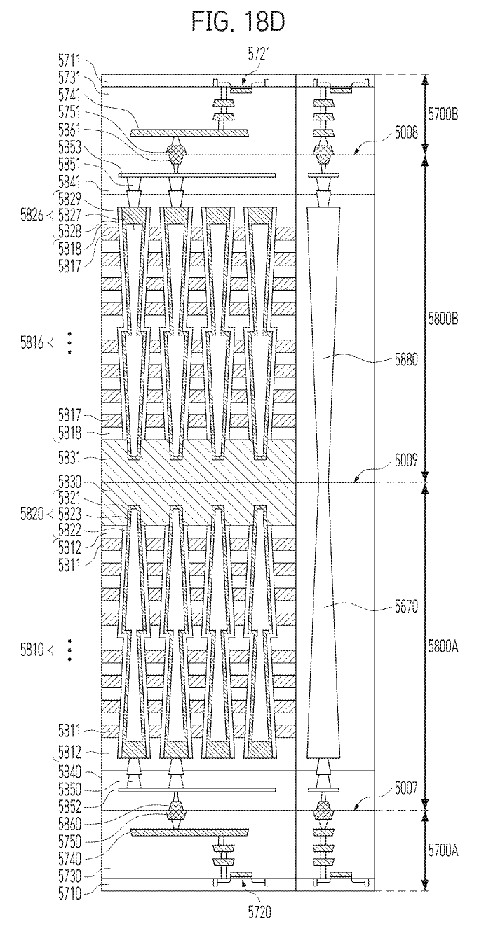

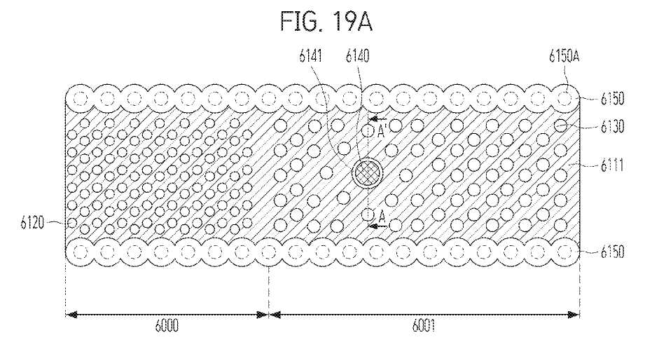

FIG. 18A is a diagram illustrating the structure of a semiconductor device in accordance with an embodiment.

Referring to FIG. 18A, the semiconductor device may include a first semiconductor structure 5100A, a second semiconductor structure 5100B, and a third semiconductor structure 5200. Bonding interfaces 5001 and 5002 may be located in the semiconductor device, and the first semiconductor structure 5100A, the second semiconductor structure 5100B, and the third semiconductor structure 5200 may be distinguished from each other by the bonding interfaces 5001 and 5002. The third semiconductor structure 5200 may be disposed between the first semiconductor structure 5100A and the second semiconductor structure 5100B. A peripheral circuit may include a first peripheral circuit and a second peripheral circuit. The first peripheral circuit and the second peripheral circuit may be distributed and disposed in the first semiconductor structure 5100A and the second semiconductor structure 5100B. The first semiconductor structure 5100A may include the first peripheral circuit, the second semiconductor structure 5100B may include the second peripheral circuit, and the third semiconductor structure 5200 may include a memory cell array.

The first semiconductor structure 5100A may include a first substrate 5110, a first transistor 5120, a first interlayer insulating layer 5130, a first interconnection structure 5140, and a first bonding pad 5150. The first transistor 5120 may be included in the first peripheral circuit. The first peripheral circuit may include a row decoder, a page buffer, an input/output circuit, a logic circuit, and the like. The first interconnection structure 5140 may be disposed in the first interlayer insulating layer 5130 and may include a via, a wiring line, and the like. The first bonding pad 5150 may be disposed at a first bonding interface 5001 and may be electrically connected to the first peripheral circuit through the first interconnection structure 5140.

The second semiconductor structure 5100B may include a second substrate 5111, a second transistor 5121, a second interlayer insulating layer 5131, a second interconnection structure 5141, and a second bonding pad 5151. The second transistor 5121 may be included in the second peripheral circuit. The second peripheral circuit may include a row decoder, a page buffer, an input/output circuit, a logic circuit, and the like. The second interconnection structure 5141 may be disposed in the second interlayer insulating layer 5131 and may include a via, a wiring line, and the like. The second bonding pad 5151 may be disposed at a second bonding interface 5002 and may be electrically connected to the second peripheral circuit through the second interconnection structure 5141.

The third semiconductor structure 5200 may include a substrate 5201, a gate structure 5210, a channel structure 5220, a source structure 5230, a third interlayer insulating layer 5240, a third interconnection structure 5250, a third bonding pad 5260, a fourth interlayer insulating layer 5270, a fourth interconnection structure 5280, a fourth bonding pad 5290, a first contact plug 5295, and a second contact plug 5297. The gate structure 5210 may include gate lines 5211 alternately stacked with insulating layers 5212. The source structure 5230 may be disposed over or under the gate structure 5210. The channel structure 5220 may include a channel layer 5221, a memory layer 5222, and/or an insulating core 5223. The channel layer 5221 may extend through the gate structure 5210 and may be connected to the source structure 5230. The third interconnection structure 5250 may be disposed in the third interlayer insulating layer 5240 and may include a via, a wiring line, and the like. For example, the third interconnection structure 5250 may include a bitline 5251. The fourth interconnection structure 5280 may be disposed in the fourth interlayer insulating layer 5270 and may include a via, a wiring line, and the like. The third bonding pad 5260 may be disposed at the first bonding interface 5001 and may be electrically connected to the memory cell array through the third interconnection structure 5250. The fourth bonding pad 5290 may be disposed at the second bonding interface 5002 and may be electrically connected to the memory cell array through the fourth interconnection structure 5280.

The first bonding pad 5150 may be electrically connected to the third bonding pad 5260 at the first bonding interface 5001, and the memory cell array may be electrically connected to the first peripheral circuit through the first bonding pad 5150 and the third bonding pad 5260. The second bonding pad 5151 may be electrically connected to the fourth bonding pad 5290 at the second bonding interface 5002, and the memory cell array may be electrically connected to the second peripheral circuit through the second bonding pad 5151 and the fourth bonding pad 5290.

The first contact plug 5295 may extend through the third interlayer insulating layer 5240 or a dummy stack, and the second contact plug 5297 may extend through the third substrate 5201. The first contact plug 5295 may be connected to the second contact plug 5297, and the first peripheral circuit may be connected to the second peripheral circuit through the first bonding pad 5150, the third bonding pad 5260, the first contact plug 5295, the second contact plug 5297, the fourth bonding pad 5290, and the second bonding pad 5151.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the second peripheral circuit, and a third wafer including the memory cell array, and bonding the first to third wafers together. For example, the third wafer may be flipped and bonded to the first wafer, and a substrate of the third wafer may be removed to form the source structure 5230. The second wafer may be flipped and bonded to the third wafer.

FIG. 18B is a diagram illustrating the structure of a semiconductor device in accordance with an embodiment.

Referring to FIG. 18B, the semiconductor device may include a first semiconductor structure 5300, a second semiconductor structure 5400A, and a third semiconductor structure 5400B. Bonding interfaces 5003 and 5004 may be located in the semiconductor device, and the first semiconductor structure 5300, the second semiconductor structure 5400A, and the third semiconductor structure 5400B may be distinguished by the bonding interfaces 5003 and 5004. The second semiconductor structure 5400A may be disposed between the first semiconductor structure 5300 and the third semiconductor structure 5400B. The first semiconductor structure 5300 may include a peripheral circuit, the second semiconductor structure 5400A may include a first memory cell array, and the third semiconductor structure 5400B may include a second memory cell array.

The first semiconductor structure 5300 may include a substrate 5310, a transistor 5320, a first interlayer insulating layer 5330, a first interconnection structure 5340, and a first bonding pad 5350. The transistor 5320 may be included in the peripheral circuit. The peripheral circuit may include a row decoder, a page buffer, an input/output circuit, a logic circuit, and the like. The first interconnection structure 5340 may be disposed in the first interlayer insulating layer 5330 and may include a via, a wiring line, and the like. The first bonding pad 5350 may be disposed at a first bonding interface 5003 and may be electrically connected to the peripheral circuit through the first interconnection structure 5340.

The second semiconductor structure 5400A may include a first gate structure 5410, a first channel structure 5420, a first source structure 5430, a second interlayer insulating layer 5440, a second interconnection structure 5450, a second bonding pad 5460, a third interlayer insulating layer 5470, a third interconnection structure 5480, and a third bonding pad 5490. The first gate structure 5410 may include first gate lines 5411 alternately stacked with first insulating layers 5412. The first source structure 5430 may be disposed over or under the first gate structure 5410. The first channel structure 5420 may include a first channel layer 5421, a first memory layer 5422, and/or a first insulating core 5423. The first channel layer 5421 may extend through the first gate structure 5410 and may be connected to the first source structure 5430. The second interconnection structure 5450 may be disposed in the second interlayer insulating layer 5440 and may include a via, a wiring line, and the like. For example, the second interconnection structure 5450 may include a bitline 5452. The third interconnection structure 5480 may be disposed in the third interlayer insulating layer 5470 and may include a via, a wiring line, and the like. The second bonding pad 5460 may be disposed at the first bonding interface 5003 and may be electrically connected to the first memory cell array through the second interconnection structure 5450. The third bonding pad 5490 may be disposed at a second bonding interface 5004, and may be electrically connected to the first memory cell array through the third interconnection structure 5480.

The third semiconductor structure 5400B may include a second gate structure 5416, a second channel structure 5426, a second source structure 5431, a fourth interlayer insulating layer 5441, a fourth interconnection structure 5451, and a fourth bonding pad 5461. The second gate structure 5416 may include second gate lines 5417 alternately stacked with second insulating layer 5418. The second source structure 5431 may be disposed over or under the second gate structure 5416. The second source structure 5431 may be electrically isolated from the first source structure 5430 and driven separately from the first source structure 5430 or may be electrically connected to the first source structure 5430 and driven in common with the first source structure 5430. The second channel structure 5426 may include a second channel layer 5427, a second memory layer 5428, and/or a second insulating core 5429. The second channel layer 5427 may extend through the second gate structure 5416 and may be connected to the second source structure 5431. The fourth interconnection structure 5451 may be disposed in the fourth interlayer insulating layer 5441 and may include a via, a wiring line, and the like. For example, the fourth interconnection structure 5451 may include a bitline 5453. The fourth bonding pad 5461 may be disposed at the second bonding interface 5004 and may be electrically connected to the second memory cell array through the fourth interconnection structure 5451.

The first bonding pad 5350 may be electrically connected to the second bonding pad 5460 at the first bonding interface 5003, and the first memory cell array may be electrically connected to the peripheral circuit through the first bonding pad 5350 and the second bonding pad 5460. The third bonding pad 5490 may be electrically connected to the fourth bonding pad 5461 at the second bonding interface 5004, and the second memory cell array may be electrically connected to the first memory cell array through the third bonding pad 5490 and the fourth bonding pad 5461.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the first wafer, and a substrate of the second wafer may be removed to form the first source structure 5430. The third wafer may be flipped and bonded to the second wafer, and a substrate of the third wafer may be removed to form the second source structure 5431.

FIG. 18C is a diagram illustrating the structure of a semiconductor device in accordance with an embodiment.

Referring to FIG. 18C, the semiconductor device may include a first semiconductor structure 5500, a second semiconductor structure 5600A, and a third semiconductor structure 5600B. Bonding interfaces 5005 and 5006 may be located in the semiconductor device, and the first semiconductor structure 5500, the second semiconductor structure 5600A, and the third semiconductor structure 5600B may be distinguished by the bonding interfaces 5005 and 5006. The second semiconductor structure 5600A may be disposed between the first semiconductor structure 5500 and the third semiconductor structure 5600B. The first semiconductor structure 5500 may include a peripheral circuit, the second semiconductor structure 5600A may include a first memory cell array, and the third semiconductor structure 5600B may include a second memory cell array.

The first semiconductor structure 5500 may include a substrate 5510, a transistor 5520, a first interlayer insulating layer 5530, a first interconnection structure 5540, and a first bonding pad 5550. The transistor 5520 may be included in the peripheral circuit. The peripheral circuit may include a row decoder, a page buffer, an input/output circuit, a logic circuit, and the like. The first interconnection structure 5540 may be disposed in the first interlayer insulating layer 5530 and may include a via, a wiring line, and the like. The first bonding pad 5550 may be disposed at a first bonding interface 5005 and may be electrically connected to the peripheral circuit through the first interconnection structure 5540.

The second semiconductor structure 5600A may include a first gate structure 5610, a first channel structure 5620, a first source structure 5630, a second interlayer insulating layer 5640, a second interconnection structure 5650, a second bonding pad 5660, a third interlayer insulating layer 5670, a third interconnection structure 5680, and a third bonding pad 5690. The first gate structure 5610 may include first gate lines 5611 alternately stacked with first insulating layers 5612. The first source structure 5630 may be disposed over or under the first gate structure 5610. The first channel structure 5620 may include a first channel layer 5621, a first memory layer 5622, and/or a first insulating core 5623. The first channel layer 5621 may extend through the first gate structure 5610 and may be connected to the first source structure 5630. The second interconnection structure 5650 may be disposed in the second interlayer insulating layer 5640 and may include a via, a wiring line, and the like. For example, the second interconnection structure 5650 may include a bitline 5652. The third interconnection structure 5680 may be disposed in the third interlayer insulating layer 5670 and may include a via, a wiring line, and the like. The second bonding pad 5660 may be disposed at a second bonding interface 5006 and may be electrically connected to the first memory cell array through the second interconnection structure 5650. The third bonding pad 5690 may be disposed at the first bonding interface 5005 and may be electrically connected to the first memory cell array through the third interconnection structure 5680.

The third semiconductor structure 5600B may include a second gate structure 5616, a second channel structure 5626, a second source structure 5631, a fourth interlayer insulating layer 5641, a fourth interconnection structure 5651, and a fourth bonding pad 5661. The second gate structure 5616 may include second gate lines 5617 alternately stacked with second insulating layer 5618. The second source structure 5631 may be disposed over or under the second gate structure 5616. The second source structure 5631 may be electrically isolated from the first source structure 5630 and driven separately from the first source structure 5630 or may be electrically connected to the first source structure 5630 and driven in common with the first source structure 5630. The second channel structure 5626 may include a second channel layer 5627, a second memory layer 5628, and/or a second insulating core 5629. The second channel layer 5627 may extend through the second gate structure 5616 and may be connected to the second source structure 5631. The fourth interconnection structure 5651 may be disposed in the fourth interlayer insulating layer 5641 and may include a via, a wiring line, and the like. For example, the fourth interconnection structure 5651 may include a bitline 5653. The fourth bonding pad 5661 may be disposed at the second bonding interface 5006 and may be electrically connected to the second memory cell array through the fourth interconnection structure 5651.

The first bonding pad 5550 may be electrically connected to the third bonding pad 5690 at the first bonding interface 5005, and the first memory cell array may be electrically connected to the peripheral circuit through the first bonding pad 5550 and the third bonding pad 5690. The second bonding pad 5660 may be electrically connected to the fourth bonding pad 5661 at the second bonding interface 5006, and the second memory cell array may be electrically connected to the first memory cell array through the second bonding pad 5660 and the fourth bonding pad 5661.

The semiconductor device may be manufactured using a method such as hybrid bonding, metal bonding, insulator bonding, or semiconductor bonding. The semiconductor device may be manufactured by manufacturing a first wafer including the peripheral circuit, a second wafer including the first memory cell array, and a third wafer including the second memory cell array, and bonding the first to third wafers together. For example, the second wafer may be flipped and bonded to the third wafer, and a substrate of the second wafer may be removed to form the first source structure 5630. The second wafer and the first wafer may be bonded, and a substrate of the third wafer may be removed to form the second source structure 5631.

FIG. 18D is a diagram illustrating the structure of a semiconductor device in accordance with an embodiment.

Referring to FIG. 18D, the semiconductor device may include a first semiconductor structure 5700A, a second semiconductor structure 5700B, a third semiconductor structure 5800A, and a fourth semiconductor structure 5800B. Bonding interfaces 5007, 5008, and 5009 may be located in the semiconductor device, and the first semiconductor structure 5700A, the second semiconductor structure 5700B, the third semiconductor structure 5800A, and the fourth semiconductor structure 5800B may be distinguished by the bonding interfaces 5007, 5008, and 5009. The third semiconductor structure 5800A and the fourth semiconductor structure 5800B may be disposed between the first semiconductor structure 5700A and the second semiconductor structure 5700B. The first semiconductor structure 5700A may include a first peripheral circuit, the second semiconductor structure 5700B may include a second peripheral circuit, the third semiconductor structure 5800A may include a first memory cell array, and the fourth semiconductor structure 5800B may include a second memory cell array.

The first semiconductor structure 5700A may include a first substrate 5710, a first transistor 5720, a first interlayer insulating layer 5730, a first interconnection structure 5740, and a first bonding pad 5750. The first transistor 5720 may be included in the first peripheral circuit. The first peripheral circuit may include a row decoder, a page buffer, an input/output circuit, a logic circuit, and the like. The first interconnection structure 5740 may be disposed in the first interlayer insulating layer 5730 and may include a via, a wiring line, and the like. The first bonding pad 5750 may be disposed at a first bonding interface 5007 and may be electrically connected to the first peripheral circuit through the first interconnection structure 5740.

The second semiconductor structure 5700B may include a second substrate 5711, a second transistor 5721, a second interlayer insulating layer 5731, a second interconnection structure 5741, and a second bonding pad 5751. The second transistor 5721 may be included in the second peripheral circuit. The second peripheral circuit may include a row decoder, a page buffer, an input/output circuit, a logic circuit, and the like. The second interconnection structure 5741 may be disposed in the second interlayer insulating layer 5731 and may include a via, a wiring line, and the like. The second bonding pad 5751 may be disposed at a second bonding interface 5008 and may be electrically connected to the second peripheral circuit through the second interconnection structure 5741.

The third semiconductor structure 5800A may include a first gate structure 5810, a first channel structure 5820, a first source structure 5830, a third interlayer insulating layer 5840, a third interconnection structure 5850, a third bonding pad 5860, and a first contact plug 5870. The first gate structure 5810 may include first gate lines 5811 alternately stacked with first insulating layers 5812. The first source structure 5830 may be disposed over or under the first gate structure 5810. The first channel structure 5820 may include a first channel layer 5821, a first memory layer 5822, and/or a first insulating core 5823. The first channel layer 5821 may extend through the first gate structure 5810 and may be connected to the first source structure 5830. The third interconnection structure 5850 may be disposed in the third interlayer insulating layer 5840 and may include a via, a wiring line, and the like. For example, the third interconnection structure 5850 may include a bitline 5852. The third bonding pad 5860 may be disposed at the first bonding interface 5007 and may be electrically connected to the first memory cell array through the third interconnection structure 5850.

The fourth semiconductor structure 5800B may include a second gate structure 5816, a second channel structure 5826, a second source structure 5831, a fourth interlayer insulating layer 5841, a fourth interconnection structure 5851, a fourth bonding pad 5861, and a second contact plug 5880. The second gate structure 5816 may include second gate lines 5817 alternately stacked with second insulating layer 5818. The second source structure 5831 may be disposed over or under the second gate structure 5816. The second source structure 5831 may be electrically connected to the first source structure 5830 and driven in common with the first source structure 5830. The second channel structure 5826 may include a second channel layer 5827, a second memory layer 5828, and/or a second insulating core 5829. The second channel layer 5827 may extend through the second gate structure 5816 and may be connected to the second source structure 5831. The fourth interconnection structure 5851 may be disposed in the fourth interlayer insulating layer 5841 and may include a via, a wiring line, and the like. For example, the fourth interconnection structure 5851 may include a bitline 5853. The fourth bonding pad 5861 may be disposed at the second bonding interface 5008 and may be electrically connected to the second memory cell array through the fourth interconnection structure 5851.

The first bonding pad 5750 may be electrically connected to the third bonding pad 5860 at the first bonding interface 5007, and the first memory cell array may be electrically connected to the first peripheral circuit through the first bonding pad 5750 and the third bonding pad 5860. The second bonding pad 5751 may be electrically connected to the fourth bonding pad 5861 at the second bonding interface 5008, and the second memory cell array may be electrically connected to the second peripheral circuit through the second bonding pad 5751 and the fourth bonding pad 5861. The first source structure 5830 may be bonded to the second source structure 5831 at a third bonding interface 5009. Thus, the first memory cell array may be electrically connected to the second memory cell array.

The first contact plug 5870 may extend through the third interlayer insulating layer 5840 or a dummy stack, and the second contact plug 5880 may extend through the fourth interlayer insulating layer 5841 or a dummy stack. The first contact plug 5870 may be connected to the second contact plug 5880, and the first peripheral circuit may be connected to the second peripheral circuit through the first bonding pad 5750, the third bonding pad 5860, the first contact plug 5870, the second contact plug 5880, the fourth bonding pad 5861, and the second bonding pad 5751.

The semiconductor device may be manufactured using a method such as hybrid bonding, metal bonding, insulator bonding, or semiconductor bonding. The semiconductor device may be manufactured by manufacturing a first wafer including the first peripheral circuit, a second wafer including the first memory cell array, a third wafer including the second peripheral circuit, and a fourth wafer including the second memory cell array, and bonding the first to fourth wafers together. For example, the second wafer may be flipped and bonded to the first wafer, and a substrate of the second wafer may be removed to form the first source structure 5830. The fourth wafer may be flipped and bonded to the third wafer, and a substrate of the fourth wafer may be removed to form the second source structure 5831. The second wafer may be bonded to the fourth wafer.

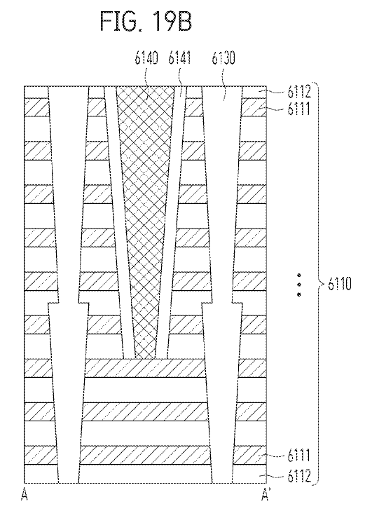

FIGS. 19A and 19B are diagrams illustrating the structure of a semiconductor device in accordance with an embodiment. FIG. 19B is a cross sectional view taken along line A A’ of FIG. 19A.

Referring to FIGS. 19A and 19B, the semiconductor device may include a gate structure 6110, channel structures 6120, supports 6130, a contact plug 6140, an insulating spacer 6141, and slit structures 6150. The term “slit structure” in the present disclosure does not indicate that a slit has a structure but rather is so named because the process of forming a slit structure utilizes a slit. The slit structures 6150 may extend in one direction, and the gate structure 6110 may be disposed between the slit structures 6150. Each of the slit structures 6150 may include an insulating material, a semiconductor material, and/or a conductive material. The gate structure 6110 may include gate lines 6111 alternately stacked with insulating layers 6112. The gate lines may be word lines, a source select line, or a drain select line.

The gate structure 6110 may include a cell region 6000 and a contact region 6001. The channel structures 6120 may be disposed in the cell region 6000 of the gate structure 6110. The channel structures 6120 may extend in a vertical direction through the gate structure 6110, and memory cells may be stacked along the channel structures 6120. The supports 6130 and the contact plug 6140 may be disposed in the contact region 6001 of the gate structure 6110. The supports 6130 may extend in the vertical direction through the gate structure 6110. Each of the supports 6130 may include an insulating material, a semiconductor material, and/or a conductive material.

The contact plug 6140 may be electrically connected to a gate line 6111. For example, the contact region 6001 of the gate structure 6110 may include a staircase structure (not shown), and the contact plug 6140 may be electrically connected to the gate line through the staircase structure. For example, the gate structure 6110 may not include the staircase structure, and the contact plug 6140 may extend through the gate structure 6110 and be electrically connected to the gate line. The insulating spacer 6141 may surround a sidewall of the contact plug 6140.

Processes of manufacturing the channel structures 6120, the supports 6130, and the slit structures 6150 may be performed simultaneously. Holes that form the channel structures 6120, the supports 6130, and the slit structures 6150 may be simultaneously formed, and sacrificial layers may be formed in the holes. The sacrificial layers are removed to form holes, and structures are formed within the holes. For example, holes 6150A arranged in a row may be formed in a region where the slit structure is to be formed. A slit may be formed by expanding the holes 6150A thereby connecting the holes 6150A together, and the slit structure 6150 may be formed in the slit. In such an example, the sidewalls of the slit structure 6150 may include irregularities or uneven surfaces.

The semiconductor device may be manufactured using a replacement process. For example, a stack may be formed including sacrificial layers alternately stacked with insulating layers, and a contact hole may be formed extending through the stack. A sacrificial pattern may be formed in the contact hole, and the sacrificial layers may be replaced with the gate lines 6111 to form the gate structure 6110. The sacrificial pattern may be removed, and the insulating spacer 6141 may be formed on sidewalls of the stack exposed by the contact hole. The contact plug 6140 may be formed within the insulating spacer 6141 formed in the contact hole.

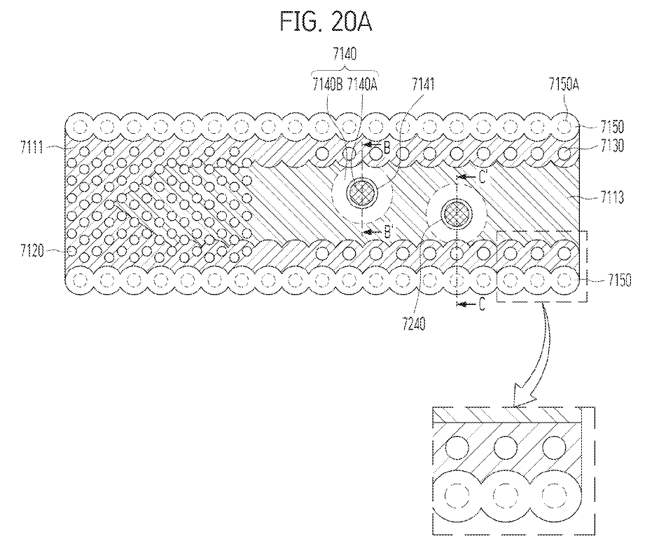

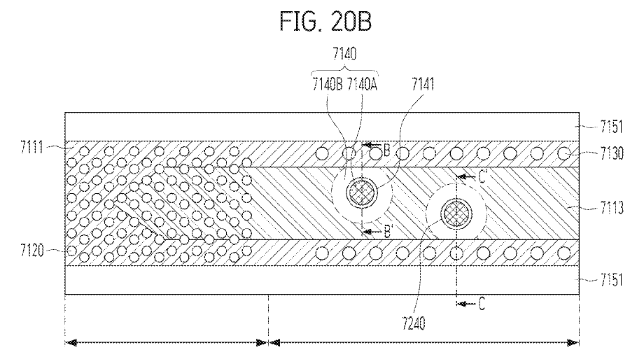

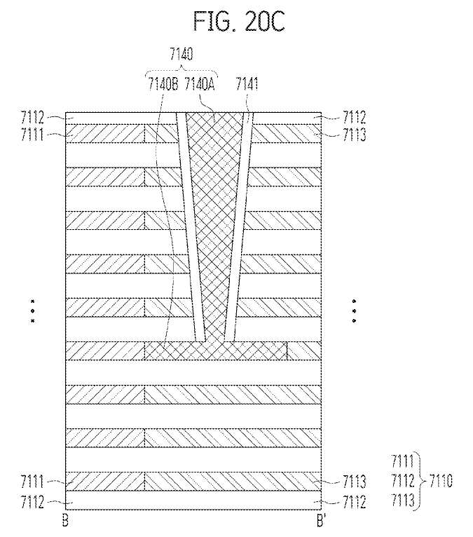

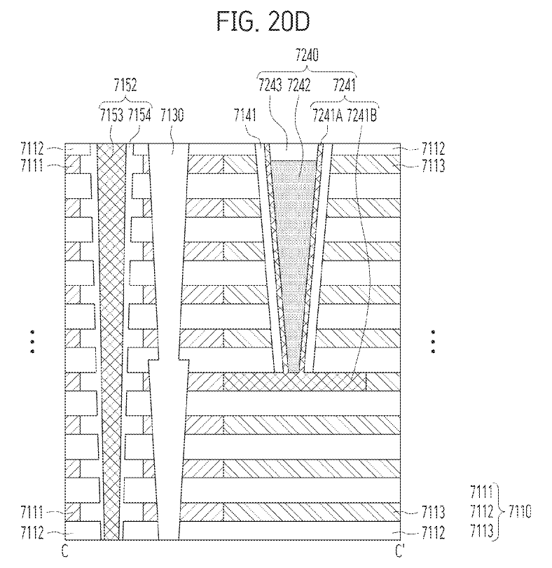

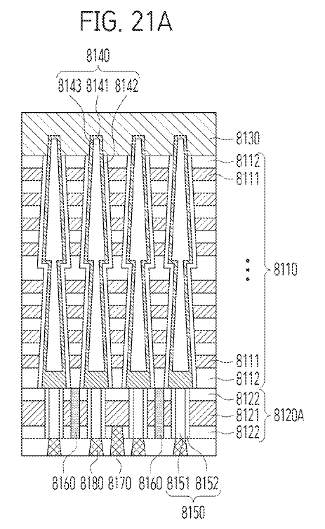

FIGS. 20A to 20D are a diagram illustrating the structure of a semiconductor device in accordance with an embodiment. FIG. 20C is a cross-sectional view taken along line B-B’ of FIG. 20A. FIG. 20D is a modified example of FIG. 20C and is a cross-sectional view taken along line C-C’ of FIG. 20A.

Referring to FIGS. 20A and 20B, the semiconductor device may include a gate structure 7110, channel structures 7120, supports 7130, a contact plug 7140, an insulating spacer 7141, and slit structures 7150 and 7151.

The slit structures 7150 may extend in one direction, and the gate structure 7110 may be disposed between the slit structures 7150. Referring to FIG. 20A, the slit structures 7150 may be formed within a slit defined by extending and connecting holes 7150A arranged in a row, and may have irregularities on their sidewalls. Referring to FIG. 20B, the slit structure 7151 may be formed within a line-shaped slit, and the sidewalls may have a linear shape without irregularities. Each of the slit structures 7150 and 7151 may include an insulating material, a semiconductor material, and/or a conductive material.

The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113. The gate line 7111 may surround the dielectric layer 7113. The interface between the gate line 7111 and the dielectric layer 7113 may be uneven or corrugated, or may have a linear shape. The supports 7130 may be disposed between the dielectric layers 7113 and the slit structures 7150, and may extend through the gate lines 7111 and the insulating layers 7112.

The contact plug 7140 may include a pillar portion 7140A and a contact portion 7140B protruding from the pillar portion 7140A. The pillar portion 7140A and the contact portion 7140B may be formed as a single layer or may be formed as separate layers. The pillar portion 7140A may extend in the vertical direction through the insulating layers 7112 and the dielectric layers 7113. The contact portion 7140B may be disposed at a level corresponding to a dielectric layer 7113 and may extend in a horizontal direction to be electrically connected to the gate line 7111. The insulating spacer 7141 may surround the pillar portion 7140A. The semiconductor device may include a plurality of contact plugs 7140, and each of the plurality of contact plugs 7140 may extend to a different depth and be connected to a different gate line 7111. In an embodiment, the pillar 7120A and the contact 7120B are formed as a single unified structure, for example, formed in one process using the same material. Alternatively, the pillar 7120A and the contact 7120B may be formed separately and connected together.

Referring to FIGS. 20A and 20D, the semiconductor device may include a gate structure 7110, channel structures 7120, a contact plug 7240, an insulating spacer 7141, supports 7130, and a slit structure 7152. The gate structure 7110 may include gate lines 7111, insulating layers 7112, and dielectric layers 7113. The gate lines 7111 are alternately stacked with the insulating layers 7112, and the insulating layers 7112 may extend between the stacked dielectric layers 7113.

The supports 7130 may extend through the gate lines 7111 that are alternately stacked with the insulating layers 7112. The supports 7130 may each include an insulating material, a semiconductor material, and/or a conductive material. The slit structure 7152 may include a structure formed in a slit used as a passage for a replacement process and may extend between adjacent gate structures 7110. For example, the slit structure 71502 may include a conductive layer 71531 and an insulating spacer 71524 surrounding sidewalls of the conductive layer 71531. The insulating spacer 71542 may include protrusions protruding toward the gate lines 7111.

The contact plug 7240 may include a barrier layer 7241, a gap-fill insulating layer 7242, and a contact pad 7243. The gap-fill insulating layer 7242 may extend in the vertical direction through the dielectric layers 7113 and the insulating layers 7112. The contact pad 7243 may be disposed over the gap-fill insulating layer 7242 and may include metal such as tungsten. The barrier layer 7241 may include a pillar portion 7241A and a contact portion 7241B. The pillar portion 7241A may surround sidewalls of the gap-fill insulating layer 7242 and the contact pad 7243. The contact portion 7241B may be disposed below a lower surface of the gap-fill insulating layer 7242 and may extend in the horizontal direction to electrically connect to the gate line 7111. The insulating spacer 7141 may surround the pillar portion 7241A. The semiconductor device may include a plurality of contact plugs 7240, and each of the plurality of contact plugs 7240 may extend to a different depth and is connected to a different gate line 7111.

The semiconductor device may be manufactured using a replacement process. For example, the gate structure 7110 may be formed by forming a stack including sacrificial layers alternately stacked with the insulating layers 7112 and replacing the sacrificial layers with the gate lines 7111 through the slit. The stack may include a cell region and a contact region, and the sacrificial layers may remain in a region of the contact region spaced apart from the slit. The dielectric layers 7113 of the gate structure 7110 may be the remaining sacrificial layers. A contact hole extending through the insulating layers 7112 and the dielectric layers 7113 may be formed, and the insulating spacer 7141 may be formed on sidewalls of the stack exposed by the contact hole. By etching the dielectric layer 7113 exposed at a lower end of the insulating spacer 7141 and the contact hole, a lower end of the contact hole may be expanded in the horizontal direction to expose the gate line 7111. The contact plug 7140 or the contact plug 7240 may be formed within the insulating spacer 7141 formed in the contact hole.

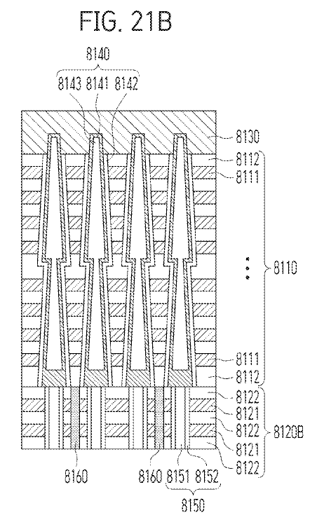

FIGS. 21A and 21B are diagrams illustrating the structure of a semiconductor device in accordance with an embodiment.

Referring to FIGS. 21A and 21B, the semiconductor device may include a first gate structure 8110, a second gate structure 8120A or 8120B, a source structure 8130, a first channel structure 8140, a second channel structure 8150, and an isolation insulating structure 8160. The first gate structure 8110 may include first gate lines 8111 alternately stacked with first insulating layers 8112. The first gate lines 8111 may be word lines or a source select line. The source structure 8130 may be disposed over the first gate structure 8110.

The second gate structure 8120A or 8120B may be disposed under the first gate structure 8110. Referring to FIG. 21A, the second gate structure 8120A may include a second gate line 8121 alternately stacked with second insulating layers 8122. The first contact plug 8170 may be connected to the second gate line 8121, and the second contact plugs 8180 may be connected to the second channel structures 8150. The first contact plug 8170 and the second contact plugs 8180 may be located in a cell region. Referring to FIG. 21B, the second gate structure 8120B may include second gate lines 8121 alternately stacked with second insulating layers 8122. Contact plugs may be connected to respective ones of the second gate lines 8121, and the contact plugs may be located in a contact region.

The second gate line 8121 may be a drain select line. The second gate line 8121 may be thicker than the first gate line 8111 or have substantially the same thickness as the first gate line 8111. The second gate line 8121 may include a different material from the first gate line 8111. For example, the first gate line 8111 may include metal such as tungsten (W) or molybdenum (Mo), and the second gate line 8121 may include polysilicon. Consecutive second gate lines 8121 disposed at the same level may be insulated by an isolation insulating structure 8160. In a plan view, the isolation insulating structures 8160 may extend in a line or a wave or zigzag shape.

The first channel structures 8140 may extend through the first gate structure 8110. The first channel structure 8140 may include a first channel layer 8141, a memory layer 8142, and/or an insulating core 8143. The second channel structures 8150 may extend through the second gate structure 8120A or 8120B and may be connected to the first channel structures 8140. The second channel structure 8150 may include a second channel layer 8151 and a gate insulating layer 8152.

The first gate structure 8110 and the second gate structure 8120A or 8120B may be formed by separate processes. For example, the first gate structure 8110 may be formed by forming a stack including sacrificial layers alternately stacked with the first insulating layers 8112 and replacing the sacrificial layers with the first gate lines 8111. The second gate structure 8120A or 8120B may be formed on the first gate structure 8110. At least one conductive layer and the second insulating layers 8122 may be formed, and the second gate lines 8121 and trenches between the second gate lines 8121 may be formed by etching at least one conductive layer and the second insulating layers 8122. The isolation insulating structures 8160 may be formed in the trenches.

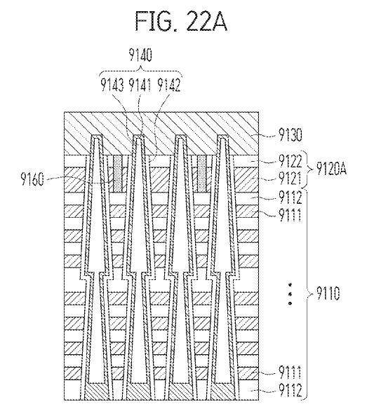

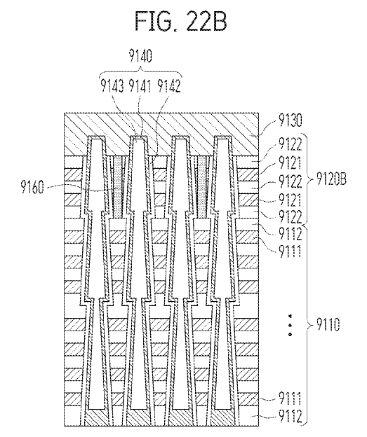

FIGS. 22A and 22B are diagrams illustrating the structure of a semiconductor device in accordance with an embodiment.

Referring to FIGS. 22A and 22B, a semiconductor device may include a first gate structure 9110, a second gate structure 9120A or 9120B, a source structure 9130, a channel structure 9140, and an isolation insulating structure 9160. The first gate structure 9110 may include first gate lines 9111 alternately stacked with first insulating layers 9112. The first gate lines 9111 may be word lines or a drain select line. The source structure 9130 may be disposed over the first gate structure 9110.

The second gate structure 9120A or 9120B may be disposed between the first gate structure 9110 and the source structure 9130. Referring to FIG. 22A, the second gate structure 9120A may include a second gate line 9121 alternately stacked with second insulating layers 9122. Referring to FIG. 22B, the second gate structure 9120B may include second gate lines 9121 alternately stacked with second insulating layers 9122. The second gate line 9121 may be a source select line. The second gate line 9121 may be thicker than the first gate line 9111 or have substantially the same thickness as the first gate line 9111. The second gate line 9121 may include a different material from the first gate line 9111. For example, the first gate line 9111 may include metal such as tungsten (W) or molybdenum (Mo), and the second gate line 9121 may include polysilicon. Consecutive second gate lines 9121 disposed at the same level may be insulated by an isolation insulating structure 9160. In a plan view, the isolation insulating structures 9160 may extend in a line or a wave or zigzag shape.

The channel structures 9140 may extend through the first gate structure 9110 and the second gate structure 9120A or 9120B. The channel structure 9140 may include a channel layer 9141, a memory layer 9142, and/or an insulating core 9143.

The first gate structure 9110 and the second gate structure 9120A or 9120B may be formed by separate processes. For example, the second gate structure 9120A or 9120B may be formed on a substrate. At least one conductive layer and the second insulating layers 9122 may be formed, and the second gate lines 9121 and trenches between the second gate lines 9121 may be formed by etching at least one conductive layer and the second insulating layers 9122. The isolation insulating structures 9160 may be formed in the trenches. The first gate structure 9110 may be formed by forming a stack including sacrificial layers alternately stacked with the first insulating layers 9112 and replacing the sacrificial layers with the first gate lines 9111. A wafer bonding process may be performed, the substrate may be removed, and the source structure 9130 may be formed. In another example, the second gate structure 9120A or 9120B including at least one conductive layer and the second insulating layers 9122 may be formed on a substrate. The first gate structure 9110 may be formed by forming a stack including sacrificial layers alternately stacked with the first insulating layers 9112 and replacing the sacrificial layers with the first gate lines 9111. A wafer bonding process may be performed, and a rear surface of the second gate structure 9120A or 9120B may be exposed by removing the substrate. The second gate lines 9121 and trenches between the second gate lines 9121 may be formed by etching at least one conductive layer and the second insulating layers 9122, and the isolation insulating structures 9160 may be formed in the trenches. The source structure 9130 may be formed.

A semiconductor device with a stabilized structure and improved reliability may be provided. In addition, a method of manufacturing a semiconductor device may be simplified at low cost.

What is claimed is:

1. A semiconductor device, comprising:
a stacked structure including word lines;
a first select line disposed over the stacked structure;
a second select line disposed over the stacked structure;
an isolation insulating pattern disposed between the first select line and the second select line;
a first channel layer extending through the stacked structure and the first select line;
a second channel layer extending through the stacked structure and the second select line;
a data storage pattern surrounding the first channel layer; and
an insulating protective layer disposed on the first select line, wherein the insulating protective layer has a protruding part that extends into the first select line.

2. The semiconductor device of claim 1, wherein the data storage pattern is not interposed between the first channel layer and the first select line.

3. A semiconductor device, comprising:
a stacked structure including word lines and insulating layers that are stacked alternately with each other;
a first select line disposed over the stacked structure;
a second select line disposed over the stacked structure;
an isolation insulating pattern disposed between the first select line and the second select line, wherein the isolation insulating pattern protrudes into a top insulating layer among the insulating layers;
a first channel layer extending through the stacked structure and the first select line;
a second channel layer extending through the stacked structure and the second select line; and
a data storage pattern between the first channel layer and the stacked structure, wherein the data storage pattern is not interposed between the first channel layer and the first select line,
wherein the isolation insulating pattern overlaps the data storage pattern in the top insulating layer.

4. The semiconductor device of claim 1, wherein the data storage pattern is not interposed between the first channel layer and the first select line.

5. A semiconductor device, comprising:
a first stacked structure including word lines and insulating layers that are stacked alternately with each other;
a first select line disposed over the first stacked structure;
a second select line disposed over the first stacked structure;
an isolation insulating pattern disposed between the first select line and the second select line;
a first channel layer extending through the first select line;
a second channel layer extending through the second select line; and
a data storage pattern extending through the first stacked structure, wherein the data storage pattern is not interposed between the first channel layer and the first select line,
wherein the first select line includes a first sidewall surrounding the first channel layer, each of the word lines includes a second sidewall surrounding the data storage pattern, and the first sidewall protrudes toward the first channel layer from the second sidewall.

6. The semiconductor device of claim 5, wherein the data storage pattern is located under the first select line.

7. The semiconductor device of claim 5, wherein the isolation insulating pattern is disposed over the first stacked structure.

8. The semiconductor device of claim 5, wherein the isolation insulating pattern overlaps the data storage pattern in a top insulating layer among the insulating layers.

9. The semiconductor device of claim 5, wherein each of the word lines has a first height and the first select line has a second height which is more than twice the first height.

10. The semiconductor device of claim 5, further comprising:
a blocking pattern surrounding the data storage pattern.

11. The semiconductor device of claim 10, wherein the blocking pattern is located under the first select line.

12. The semiconductor device of claim 11, wherein the blocking pattern is not interposed between the first channel layer and the first select line.

13. The semiconductor device of claim 10, wherein the first channel layer extends into the first stacked structure.

14. The semiconductor device of claim 10,
wherein the isolation insulating pattern has a first width between the first select line and the second select line, and
wherein the isolation insulating pattern has a second width greater than the first width over the first channel layer and the second channel layer.

15. The semiconductor device of claim 5, further comprising:
a third channel layer extending through the first stacked structure and connected to the first channel layer.

16. The semiconductor device of claim 15, wherein the data storage pattern is disposed between the third channel layer and the first stacked structure.

17. The semiconductor device of claim 5, further comprising:
a first peripheral circuit disposed under the first stacked structure; and
a first bonding pad disposed between the first stacked structure and the first peripheral circuit,
wherein the first bonding pad is electrically connected to the first peripheral circuit.

18. The semiconductor device of claim 17, wherein the first channel layer is connected to the first peripheral circuit through the first bonding pad.

19. The semiconductor device of claim 5, further comprising:
a second stacked structure disposed over the first stacked structure; and
a second bonding pad disposed between the first stacked structure and the second stacked structure.

20. The semiconductor device of claim 5, further comprising:
a second peripheral circuit disposed over the first stacked structure; and
a second bonding pad disposed between the first stacked structure and the second stacked structure.
